(19) United States
(12) Patent Application Publication
(10) Pub. No.: US 2024/0383157 A1
(43) Pub. Date: Nov. 21, 2024

(54) SUBSTRATE TRANSFER ROBOT, SUBSTRATE TRANSFER SYSTEM, AND SUBSTRATE TRANSFER METHOD

(71) Applicant: KABUSHIKI KAISHA YASKAWA DENKI, Fukuoka (JP)

(72) Inventors: Koji NAGAFUCHI, Fukuoka (JP); Makoto TARUNO, Fukuoka (JP); Hiroki SANEMASA, Fukuoka (JP); Takashi MINAMI, Fukuoka (JP)

(21) Appl. No.: 18/647,509

(22) Filed: Apr. 26, 2024

(30) Foreign Application Priority Data
May 16, 2023 (JP) 2023-080882

(51) Int. Cl. B25J 15/06; B25J 11/00; B25J 13/08; B25J 15/00

(52) U.S. Cl. CPC B25J 15/0616; B25J 11/0095; B25J 13/085; B25J 15/0014

(57) ABSTRACT

A substrate transfer robot includes: a hand that supports a substrate; and an arm that operates the hand. The hand includes an adsorption holder that holds a back surface of the substrate by adsorption, and is stretchable to lower a height position of an upper end thereof, a friction holder that holds the back surface by friction in a state where the adsorption holder supporting the substrate contracts, and a non-contact holder that holds the back surface in a non-contact manner, in a state where the adsorption holder and the friction holder hold the back surface.

### CROSS-REFERENCE TO RELATED APPLICATIONS

This application is based on and claims priority from Japanese Patent Application No. 2023-080882, filed on May 16, 2023, with the Japan Patent Office, the disclosure of which is incorporated herein in its entirety by reference.

### TECHNICAL FIELD

The present disclosure relates to a substrate transfer robot, a substrate transfer system, and a substrate transfer method.

### BACKGROUND

Japanese Patent Laid-Open Publication No. 2014-130899 discloses a substrate transfer apparatus capable of detecting that a substrate is placed on arms in a corrected state when transferred.

### SUMMARY

The present disclosure provides a substrate transfer robot, a substrate transfer system, and a substrate transfer method, which are useful for stabilizing a transfer operation.

According to an aspect of the present disclosure, a substrate transfer robot includes: a hand that supports a substrate; and an arm that operates the hand. The hand includes an adsorption holder that holds a back surface of the substrate by adsorption and is stretchable to lower a height position of an upper end thereof, a friction holder that holds the back surface by friction in a state where the adsorption holder supporting the substrate contracts, and a non-contact holder that holds the back surface in a non-contact manner, in a state where the adsorption holder and the friction holder hold the back surface.

According to another aspect of the present disclosure, a substrate transfer system includes: a substrate transfer robot that includes a hand and transfers a substrate while supporting the substrate by the hand; a cassette in which the substrate is placed before or after being transferred by the substrate transfer robot; and a transfer controller that controls the substrate transfer robot to transfer the substrate between the cassette and a predetermined position distant from the cassette. The hand includes an adsorption holder that holds a back surface of the substrate by adsorption and is stretchable to lower a height position of an upper end thereof, a friction holder that holds the back surface by friction in a state where the adsorption holder supporting the substrate contracts, and a non-contact holder that holds the back surface in a non-contact manner, in a state where the adsorption holder and the friction holder hold the back surface.

According to yet another aspect of the present disclosure, a substrate transfer method includes: transferring a substrate by a substrate transfer robot including a hand supporting the substrate. The hand includes an adsorption holder that holds a back surface of the substrate by adsorption and is stretchable to lower a height position of an upper end thereof, a friction holder that holds the back surface by friction in a state where the adsorption holder supporting the substrate contracts, and a non-contact holder that holds the back surface in a non-contact manner, in a state where the adsorption holder and the friction holder hold the back surface. In the transferring, the substrate transfer robot is controlled to transfer the substrate in a state where each of the adsorption holder, the friction holder, and the non-contact holder holds the back surface.

The present disclosure provides a substrate transfer robot, a substrate transfer system, and a substrate transfer method, which are useful for stabilizing a transfer operation.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating an example of a substrate transfer system.

FIG. 2 is a schematic view illustrating an example of substrates placed in a cassette.

FIG. 3 is a top view illustrating an example of a hand.

FIG. 4A is a schematic view illustrating a relationship between adsorption units and friction holding units.

FIG. 4B is a schematic view illustrating an example of a suction path connected to the adsorption units.

FIG. 5A is a cross-sectional view schematically illustrating an example of an adsorption unit in a state where the adsorption unit is not supporting a workpiece.

FIG. 5B is a cross-sectional view schematically illustrating an example of an adsorption unit in a state where the adsorption unit is supporting a workpiece.

FIG. 6A is a schematic view illustrating a relationship between friction holding units and non-contact holding units. FIG. 6B is a schematic view illustrating an example of an air supply path connected to the non-contact holding units.

FIG. 7 is a block diagram illustrating an example of a functional configuration of a robot controller.

FIG. 8 is a block diagram illustrating an example of a hardware configuration of the robot controller.

FIG. 9 is a flowchart illustrating an example of a series of processes performed by the robot controller.

FIG. 10 is a flowchart illustrating an example of a series of processes performed by the robot controller.

FIGS. 11A and 11B are schematic views illustrating an example of a state where a hand is positioned.

FIG. 12 is a flowchart illustrating an example of a series of processes performed by the robot controller.

FIG. 13 is a flowchart illustrating an example of a series of processes performed by the robot controller.

FIG. 14 is a schematic view illustrating an example of a state where a scanning operation is performed.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, embodiments will be described with reference to the drawings. In the descriptions, the same components or components having the same function will be denoted by the same reference numerals, and overlapping descriptions will be omitted.

### [Substrate Transfer System]

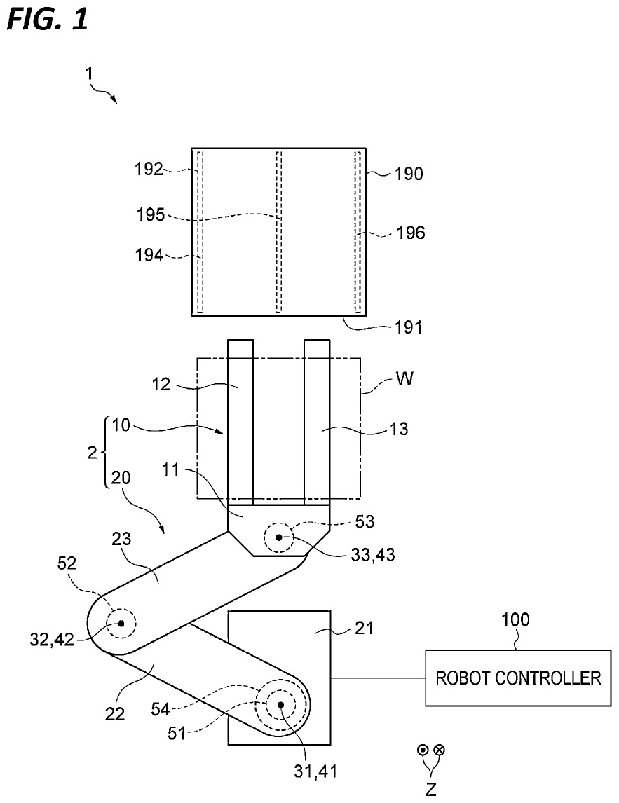

FIG. 1 schematically illustrates a substrate transfer system according to an embodiment. A substrate transfer system 1 illustrated in FIG. 1 is a system that transfers a processing target substrate W. For example, the substrate transfer system 1 transfers the substrate W in a substrate processing apparatus. An example of the substrate W is, but is not limited to, a rectangular panel formed of a resin material such as glass epoxy, or glass. The substrate W may be a semiconductor substrate.

The substrate transfer system 1 may transfer a plurality of types of substrates W, which are different from each other in at least one of size and mass. When a plurality of substrates W, including the plurality of types of substrates W, is transferred, the substrate transfer system 1 transfers the substrates W one by one. The plurality of types of substrates W transferred by the substrate transfer system 1 may have different thicknesses and substantially the same size when viewed from the thickness direction. Hereinafter, descriptions will be made assuming an example where the workpiece to be processed by the substrate transfer system 1 is the substrate W having a rectangular shape.

The substrate transfer system 1 includes, for example, a cassette 190, a substrate transfer robot 2, and a robot controller 100.

### (Cassette)

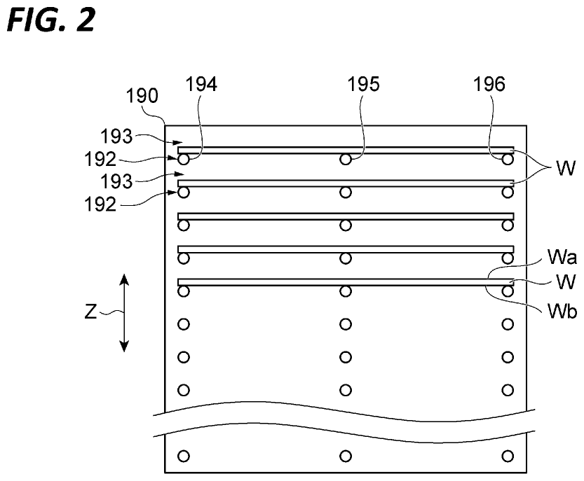

In the cassette 190, substrates W transferred or to be transferred by the substrate transfer robot 2 are placed. As illustrated in FIG. 2, for example, the cassette 190 accommodates a plurality of substrates W in a state of being arranged vertically. The cassette 190 includes multi-tier substrate support units 192. Each of the multi-tier substrate support units 192 supports a substrate W to be horizontal. The substrate support unit 192 supports one of the main surfaces of the substrate W. Of the pair of main surfaces of the substrate W, the main surface supported by, for example, the substrate support unit 192 (lower surface) will be referred to as the “back surface Wb,” and the main surface opposite to the back surface Wb (upper surface) will be referred to as the “front surface Wa.”

The multi-tier substrate support units 192 divide the interior of the cassette 190 into multi-tier slots 193. Each slot 193 is formed by a pair of substrate support units 192 adjacent to each other in the vertical direction (the Z-axis direction in FIG. 2) or by a substrate support unit 192 and a portion of the housing of the cassette 190. The cassette 190 has an opening 191. The opening 191 is formed such that the substrate W may be carried in and out along one horizontal direction.

Each of the multi-tier substrate support units 192 may include a plurality of rods, which include, for example, rods 194, 195, and 196. The rods 194, 195, and 196 are parallel to each other, and arranged at the same height. Each of the rods 194, 195, and 196 extends along a horizontal direction. The cassette 190 may be configured in any way as long as the substrates W transferred or to be transferred by the substrate transfer robot 2 may be placed.

### (Substrate Transfer Robot)

Returning to FIG. 1, the substrate transfer robot 2 transfers the substrate W while supporting the substrate W with a hand thereof. For example, the substrate transfer robot 2 transfers the substrate W between the cassette 190 and a predetermined position distant from the cassette 190. The substrate transfer robot 2 may transfer the substrate W by receiving the substrate W from the cassette 190, or transfer the substrate W to deliver the substrate W to the cassette 190. The substrate transfer robot 2 includes, for example, a hand 10 and a multi-joint arm 20 (arm).

The hand 10 supports the substrate W. The hand 10 supports the back surface Wb of the substrate W in the state where the substrate W is horizontal. The hand 10 has, for example, a fork shape when viewed from above, and includes a base portion 11, a first fork portion 12, and a second fork portion 13. The base portion 11 expands along the horizontal direction, and is connected to one end of the first fork portion 12 and one end of the second fork portion 13. The base portion 11 is also called a fork socket, and each of the first fork portion 12 and the second fork portion 13 is also called a fork tine.

Each of the first fork portion 12 and the second fork portion 13 extends in one horizontal direction to be away from the base portion 11. The first fork portion 12 and the second fork portion 13 are arranged parallel to each other when viewed from above. The substrate W is held by the first fork portion 12 and the second fork portion 13. The first fork portion 12 and the second fork portion 13 hold the back surface Wb of the substrate W by three different holding methods including, for example, adsorption, friction, and non-contact adsorption. Details of the holding of the substrate W by the hand 10 will be described later.

The multi-joint arm 20 operates the hand 10. The multi-joint arm 20 moves the hand 10 to transfer the substrate W between the cassette 190 and the predetermined position distant from the cassette 190. The multi-joint arm 20 may move the hand 10 to transfer the substrate W from the predetermined position to the cassette 190 and deliver the substrate W to the cassette 190. The multi-joint arm 20 may move the hand 10 to receive the substrate W from the cassette 190 and transfer the substrate W from the cassette 190 to the predetermined position.

The multi-joint arm 20 is configured such that the position of the hand 10 in the horizontal plane and the posture of the hand 10 around an axis along the vertical direction may be changed by the rotation of one or more joints. The multi-joint arm 20 includes, for example, a base portion 21, a first arm 22, a second arm 23, an actuator 51, an actuator 52, and an actuator 53.

The base portion 21 may be fixed around the cassette 190, or may be installed on a movable unit that moves the base portion 21 to change the position of the base portion 21 in the horizontal direction. The first arm 22 is connected to the base portion 21 to be rotatable around a vertical axis 31, and extends in a direction away from the axis 31. The second arm 23 is connected to the end of the first arm 22 to be rotatable around a vertical axis 32, and extends in a direction away from the axis 32.

The base portion 11 of the hand 10 is connected to the end of the second arm 23. The base portion 11 is connected to the end of the second arm 23 to be rotatable, for example, around a vertical axis 33. In the present example, the multi-joint arm 20 has three joints including a joint 41 that connects the base portion 21 and the first arm 22, a joint 42 that connects the first arm 22 and the second arm 23, and a joint 43 that connects the second arm 23 and the base portion 11.

The actuators 51, 52, and 53 drive the joints 41, 42, and 43, respectively. For example, the actuator 51 rotates the first arm 22 around the axis 31, the actuator 52 rotates the second arm 23 around the axis 32, and the actuator 53 rotates the base portion 11 (the hand 10) around the axis 33. The multi-joint arm 20 may further include the actuator 54. The actuator 54 moves the first arm 22 up and down along the axis 31. The actuators 51, 52, 53, and 54 are, for example, electrically operated, but are not limited thereto.

While FIG. 1 illustrates an example where each of the actuators 51, 52, 53, and 54 is disposed at the same position as the object to be driven by the actuator, at least one of the actuators 51, 52, 53, and 54 may be disposed at a position apart from the driving object to be connected to the driving object via a power transmission mechanism such as a link, a timing belt, or a gear.

The configuration of the arm such as the multi-joint arm 20 in the substrate transfer robot 2 may be modified as long as the position of the hand 10 may be changed in the horizontal direction. The multi-joint arm 20 may have four or more joints. Any two or more of the joints 41, 42, and 43 may be driven by a common actuator via, for example, links.

### <Holding of Substrate by Hand>

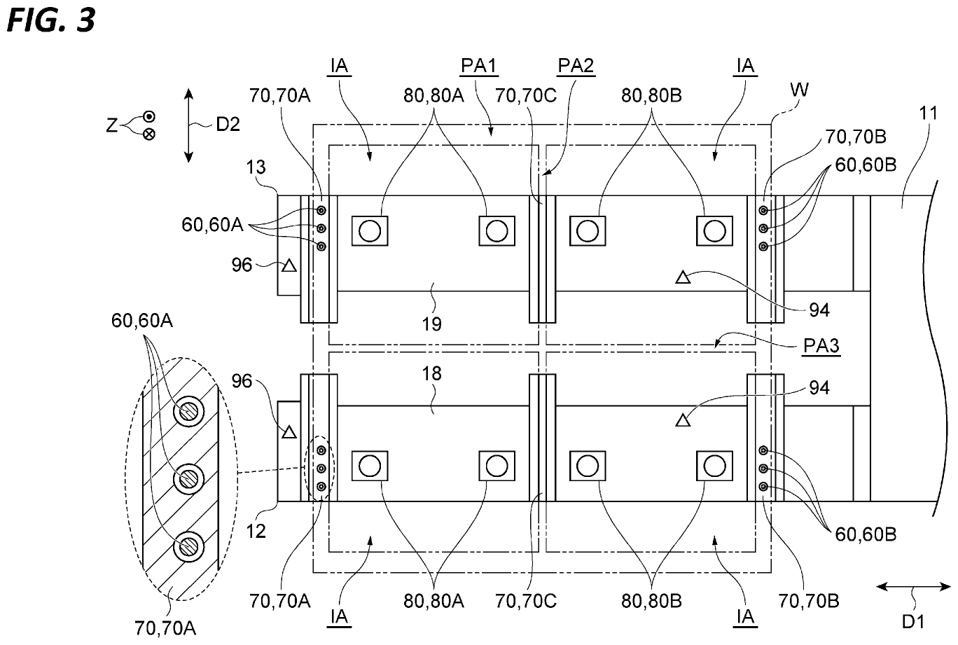

Subsequently, details of the holding of the substrate W by the hand 10 will be described with reference to FIGS. 3 to 6. In the descriptions herein below, the direction in which each of the first fork portion 12 and the second fork portion 13 extends will be referred to as the “direction D1,” and the direction in which the first fork portion 12 and the second fork portion 13 are arranged, that is, the direction orthogonal to the direction D1 and the Z-axis direction (vertical direction) will be referred to as the “direction D2.” Further, the substrate W will be described assuming the state where the substrate W is being supported by the hand 10. The hand 10 may support the substrate W such that when viewed from above, one pair of edges of the rectangular substrate W is parallel along the direction D1 (predetermined direction), and the other pair of edges of the substrate W is parallel along the direction D2.

The first fork portion 12 and the second fork portion 13 are configured to hold the back surface Wb of the substrate W. The second fork portion 13 is disposed while being spaced apart from the first fork portion 12 (fork portion) in the direction D2 (width direction). The back surface Wb of the substrate W is set to have a region where contact is permitted during the transfer of the substrate W (hereinafter, referred to as the “contact region”) and a region where contact is not permitted during the transfer of the substrate W (hereinafter, referred to as the “non-contact region”). The contact region and the non-contact region may be set in any way according to, for example, the type of the substrate W. The first fork portion 12 and the second fork portion 13 are provided with at least three types of holding units according to the contact region and the non-contact region of the substrate W to be transferred.

For example, in the back surface Wb of the substrate W, regions PA1, PA2, and PA3 are set as contact regions, and four regions IA are set as non-contact regions. The region PA1 is disposed at the periphery of the back surface Wb, and has a frame shape. The periphery of the back surface Wb indicates a frame-shaped region formed by the peripheral edge (outer edge) of the back surface Wb and a neighboring portion of the peripheral edge. The width (predetermined width) of the frame-shaped region PA1 is smaller than half or a quarter of the length of the substrate W in the direction D1 or D2.

The region PA2 is a region formed to extend along the direction D2 from the inside of the region PA1 (inside the inner edge of the region PA1). The region PA2 may be disposed at the center of the back surface Wb of the substrate W in the direction D1. One end of the region PA2 in the direction D2 is connected to one of the portions of the region PA1 that extend in the direction D1, and the other end of the region PA2 in the direction D2 is connected to the other portion of the region PA1 that extends in the direction D1.

The region PA3 is a region formed to extend along the direction D1 from the inside of the region PA1. The region PA3 may be disposed at the center of the back surface Wb of the substrate W in the direction D2. One end of the region PA3 in the direction D1 is connected to one of the portions of the region PA1 that extend in the direction D2, and the other end of the region PA3 in the direction D1 is connected to the other portion of the region PA1 that extends in the direction D2. The region PA2 and PA3 may intersect at the central portion including the center of the back surface Wb.

The four regions IA are regions of the back surface Wb other than the contact regions including the regions PA1, PA2, and PA3. The four regions IA are arranged in a matrix form having two rows and two columns in the plane expanding in the directions D1 and D2. The region PA2 is disposed between one set of regions IA arranged in the direction D2 and another set of regions IA arranged in the direction D2, and the region PA3 is disposed between one set of regions IA arranged in the direction D1 and another set of regions IA arranged in the direction D1. The areas of the four regions IA may be substantially equal to each other.

With respect to a virtual line passing through the center of the back surface Wb along the direction D1, the regions PA1, PA2, and PA3, and the four regions IA may be line symmetrical. With respect to a virtual line passing through the center of the back surface Wb along the direction D2, the regions PA1, PA2, and PA3, and the four regions IA may be line symmetrical. The first fork portion 12 may hold the region located on one side with respect to the region PA3 in the direction D2, and the second fork portion 13 may hold the region located on the other side with respect to the region PA3 in the direction D2. In the direction D2, the width (maximum width) of the first fork portion 12 is smaller than the width of the substrate W, and the width (maximum width) of the second fork portion 13 is smaller than the width of the substrate W.

When focusing on the portion of the back surface Wb that is held by the first fork portion 12, one of the portions of the region PA1 that extend in the direction D2, the region IA, the region PA2, the region IA, and the other portion of the region PA1 that extends in the direction D2 are arranged in this order. Also, when focusing on the portion of the back surface Wb that is held by the second fork portion 13, the order of the regions is the same. One of the portions of the region PA1 that extend in the direction D2 corresponds to one end of the back surface Wb in the direction D1, and the other portion of the region PA1 that extends in the direction D2 corresponds to the other end of the back surface Wb in the direction D1.

The first fork portion 12 includes one or more adsorption units 60, one or more friction holding units 70, and one or more non-contact holding units 80. The one or more adsorption units 60, the one or more friction holding units 70, and the one or more non-contact holding units 80 are provided on a body portion 18 of the first fork portion 12. The body portion 18 is formed in a plate shape. When viewed from above, the body portion 18 may have a rectangular shape that extends in the direction D1, and the width of the body portion 18 in the direction D2 may be substantially constant. Any one of the one or more adsorption units 60, the one or more friction holding units 70, and the one or more non-contact holding units 80 may be fixed (connected) to the upper surface of the body portion 18 via a fixing member.

### <Adsorption Unit>

The one or more adsorption units 60 hold the back surface Wb of the substrate W by adsorption. For example, a plurality of adsorption units 60 is provided in the first fork portion 12. In the case where the plurality of adsorption units 60 are provided, the plurality of adsorption units 60 may have the same configuration. The adsorption units 60 adsorb a portion of the regions of the back surface Wb in the state where a portion of the adsorption units 60 comes into contact with the back surface Wb. All of the plurality of adsorption units 60 may hold the region PA1, which is a portion of the contact regions, by adsorption. In the example illustrated in FIG. 3, six adsorption units 60 are provided as the one or more adsorption units 60.

In an example, three of the six adsorption units 60 hold one end of the back surface Wb in the direction D1 by adsorption, and the remaining three adsorption units 60 hold the other end of the back surface Wb in the direction D1 by adsorption. In FIG. 3, “60A” indicates the adsorption units 60 holding the end of the back surface Wb far from the base portion 11 in the direction D1, and “60B” indicates the adsorption units 60 holding the end of the back surface Wb close to the base portion 11 in the direction D1. That is, the adsorption units 60A (first adsorption units) hold one end (first end) of the back surface Wb in the direction D1 by adsorption, and the adsorption units 60B (second adsorption units) hold the other end (second end) of the back surface Wb in the direction D1 by adsorption.

The three adsorption units 60A that hold one end (distal end) of the back surface Wb by adsorption are arranged side by side in the direction D2. The three adsorption sections 60B that hold the other end (proximal end) of the back surface Wb by adsorption are arranged side by side in the direction D2. Each adsorption unit 60A may be disposed at the same position as its corresponding adsorption unit 60B in the direction D2. The three adsorption units 60A and the three adsorption units 60B may be arranged close to one of both ends of the body portion 18 that is far from the second fork portion 13 (close to the outside) in the direction D2.

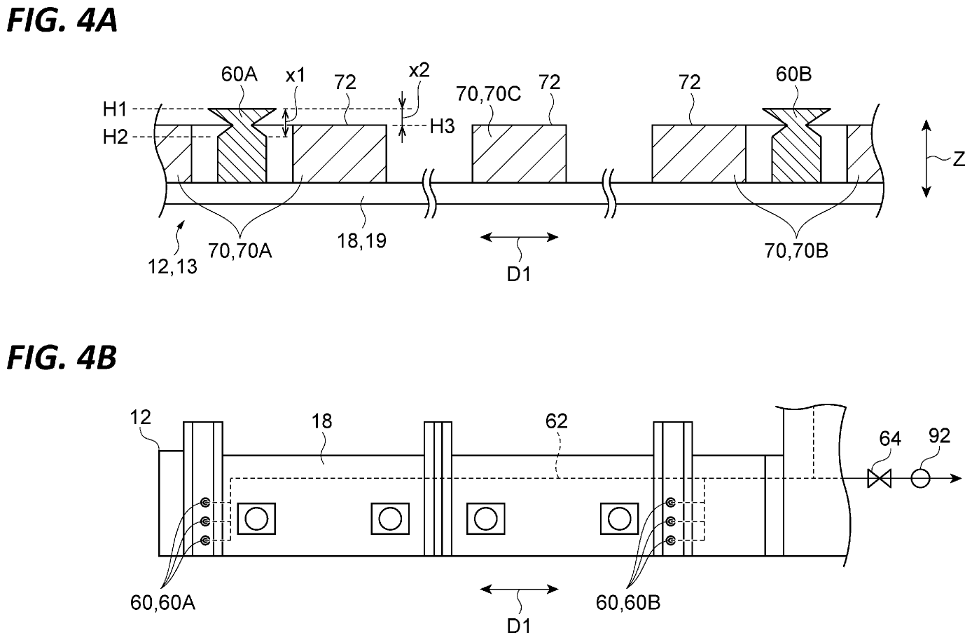

FIG. 4A illustrates the relationship between the adsorption units 60 and the friction holding units 70 in the state where the hand 10 is not supporting the substrate W. Each adsorption unit 60 is stretchable such that the height position of the upper end of the adsorption unit 60 becomes lower. In the descriptions herein, the “height position” of a part indicates the height position of the part in the vertical direction, and the upper end of a member indicates the top position of the member (the uppermost position). The adsorption unit 60 may contract from a height position H1 (first height position) to a height position H2 (second height position). The height position H1 indicates the height position of the upper end of the adsorption unit 60 in the state where the adsorption unit 60 does not contract since no external force acts on the adsorption unit 60. The height position H1 also indicates the height position of the upper end of the adsorption unit 60 in the state where the hand 10 is not supporting the substrate W.

The height position H2 indicates the height position of the upper end of the adsorption unit 60 in the state where the adsorption unit 60 contracts since an external force acts on the adsorption unit 60 in the maximum amount to which the adsorption unit 60 can contract. That is, the difference between the height position H1 and the height position H2 indicates the maximum contraction amount (retraction amount). The configuration that the adsorption unit 60 can contract to the height position H2 does not indicate that the adsorption unit 60 can contract in the state where the hand 10 is supporting the substrate W, but indicates the performance of the adsorption unit 60 itself. Thus, it may not be said that the upper end of the adsorption unit 60 retracts to the height position H2 by another member in the state where the hand 10 is supporting the substrate W.

The substrate transfer robot 2 has a suction path 62 and an open/close valve 64 as illustrated in FIG. 4B. The suction path 62 is a flow path that connects each of the plurality of adsorption units 60 and a suction pump (vacuum pump) provided in the substrate transfer system 1. At least a portion of the suction path 62 may be provided inside the body portion 18 of the first fork portion 12. The open/close valve 64 switches the open/close states of the suction path 62. When the open/close valve 64 is in the open state, each of the plurality of adsorption units 60 and the suction pump are connected, so that each of the plurality of adsorption units 60 may adsorb the back surface Wb. When the open/close valve 64 is in the close state, the connection between each of the plurality of adsorption units 60 and the suction pump is shut off, so that each of the plurality of adsorption units 60 does not adsorb the back surface Wb.

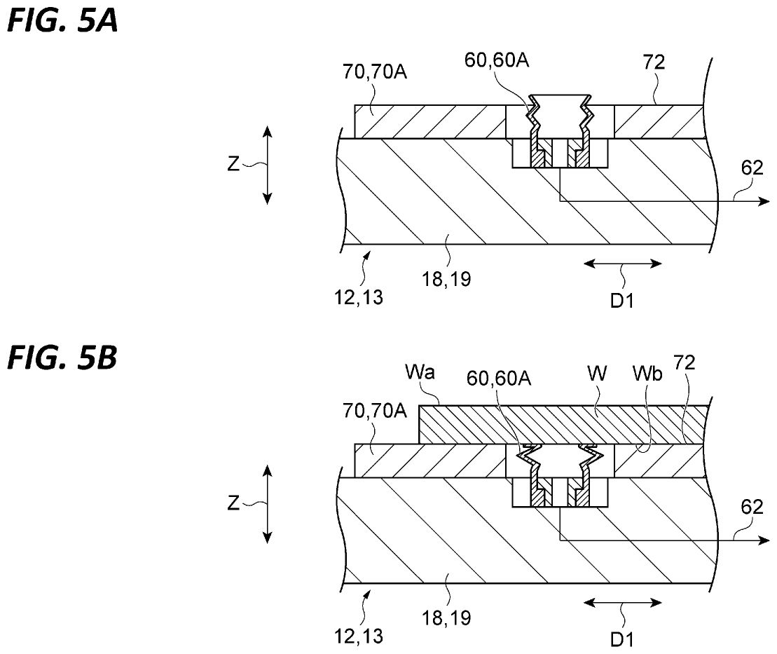

Each adsorption unit 60 may be formed in a cylindrical shape, and has an interior space with an opened upper end (see also, e.g., FIG. 5A). When focusing on a single adsorption unit 60, the adsorption unit 60 is connected to the suction pump, and the opening formed at the upper end of the adsorption unit 60 is blocked by the back surface Wb of the substrate W, so that the interior space of the adsorption unit 60 substantially enters a vacuum state (negative pressure state). As a result, the adsorption unit 60 holds the corresponding region of the back surface Wb by adsorption.

FIGS. 5A and 5B schematically illustrate cross-sectional views including the central axis of the adsorption unit 60, which are cut along the plane following the direction D1. FIG. 5A illustrates the cross-sectional view in the state where the hand 10 is not supporting the substrate W. FIG. 5B illustrates the cross-sectional view in the state where the hand 10 is supporting the substrate W, and the adsorption unit 60 contracts. As illustrated in FIGS. 5A and 5B, at least a portion of the adsorption unit 60 may have a bellows shape (pleated tube shape). The adsorption unit 60 may be formed of any material as long as it is stretchable, and is formed of, for example, rubber such as fluoro rubber.

### <Friction Holding Unit>

The one or more friction holding units 70 hold the back surface Wb of the substrate W by friction. As illustrated in FIG. 3, the first fork portion 12 is provided with, for example, a plurality of friction holding units 70. Each of the plurality of friction holding units 70 may come into contact with the back surface Wb when the adsorption unit 60 (each of the plurality of adsorption units 60) supporting the substrate W contracts. The back surface Wb may come into contact with the upper end of each of the plurality of friction holding units 70, in the state where the adsorption unit 60 contracts while adsorbing the back surface Wb. When the plurality of friction holding units 70 are provided, the height positions of the upper ends of the plurality of friction holding units 70 are substantially equal to each other.

Each friction holding unit 70 holds a portion of the regions of the back surface Wb by friction, in the state where a portion of the friction holding unit 70 is in contact with the back surface Wb. The friction holding unit 70 may be formed of any material as long as it may regulate the movement of the substrate W in the direction along the back surface Wb by friction when the back surface Wb comes into contact with the friction holding unit 70. For example, the friction holding unit is formed of rubber. The friction holding unit 70 may include a flat holding surface 72 that comes into contact with the back surface Wb of the substrate W (see, e.g., FIGS. 4A and 4B). The holding surface 72 of the friction holding unit 70 corresponds to the upper surface of the friction holding unit 70, and expands in the horizontal direction.

The friction holding unit 70 may be formed to extend along the direction D2. In plan view, the friction holding unit 70 (the holding surface 72 of the friction holding unit 70) may have a rectangular shape extending along the direction D2. When focusing on a single friction holding unit 70, the maximum width of the friction holding unit 70 may be larger than the maximum width of the body portion 18 of the first fork portion 12, in the direction D2. When viewed from above, a portion of the friction holding unit 70 may protrude from the body portion 18 in the space between the body portion 18 and the second fork portion 13. The friction holding unit 70 may not protrude from the body portion 18 at the outside of the body portion 18, which is opposite to the space above.

In the example illustrated in FIG. 3, three friction holding units 70 are provided on the body portion 18 of the first fork portion 12. In an example, one of the three friction holding units 70 holds one end of the back surface Wb in the direction D1 by friction, and another of the three friction holding units 70 holds the other end of the back surface Wb in the direction D1 by friction. The remaining one of the three friction holding units 70 holds a portion of the region PA2 extending along the direction D2 by friction.

In FIG. 3, “70A” indicates the friction holding unit 70 that holds one of both ends of the back surface Wb far from the base portion 11 in the direction D1, and “70B” indicates the friction holding unit 70 that holds the other of both ends of the back surface Wb close to the base portion 11 in the direction D1. Further, “70C” indicates the friction holding unit 70 that holds a portion of the region PA2. The friction holding unit 70A, the friction holding unit 70C, and the friction holding unit 70B are arranged in this order in the direction D1. The widths of the friction holding units 70A, 70B, and 70C in the direction D2 may be substantially equal to each other, or the positions thereof in the direction D2 may be the same.

The friction holding unit 70A is provided such that its holding surface 72 surrounds each adsorption unit 60A. For example, when viewed from above, a circular hole is formed in the friction holding unit 70A to provide each adsorption unit 60A therein, and an annular gap is formed between the outer periphery of each adsorption unit 60A and the friction holding unit 70A (the inner periphery of the hole) (see, e.g., the enlarged view in FIG. 3). When viewed from above, the area of the holding surface 72 of the friction holding unit 70A may be larger than the area surrounded by the outer periphery of the adsorption unit 60A. The relationship between the friction holding unit 70B and the adsorption unit 60B may be similar to the relationship between the friction holding unit 70A and the adsorption unit 60A. In the enlarged view of FIG. 3, the friction holding unit 70A and the adsorption unit 60A are hatched to facilitate the understanding.

As illustrated in FIG. 4A, the height position H1 of the upper end of the adsorption unit 60 is higher than a height position H3 of the upper end of the friction holding unit 70, in the state where the hand 10 is not supporting the substrate W. The height position H3 may be defined by the height position of the holding surface 72 of the friction holding unit 70. The upper end of the friction holding unit 70 (the holding surface 72) may be located between the height position H1 and the height position H2. In this case, the difference x1 between the height position H1 and the height position H2 (maximum contraction amount) is larger than the difference x2 between the height position H1 and the height position H3. Since the back surface Wb comes into contact with the holding surface 72 of the friction holding unit 70 in the state where the adsorption unit 60 contracts while adsorbing the back surface Wb (see, e.g., FIG. 5B), the adsorption unit 60 contracts to a height position higher than the height position H2. According to the size of the difference x2, the material of the adsorption unit 60, and the type of the substrate W, the back surface Wb may come into contact with the holding surface 72 due to, for example, the warping of the substrate W, even when the adsorption unit 60 does not contract. Even in this case, the back surface Wb still comes into contact with the holding surface 72 of the friction holding unit 70 in the state where the adsorption unit 60 contracts while adsorbing the back surface Wb.

### <Non-Contact Holding Unit>

The one or more non-contact holding units 80 hold the back surface Wb in the non-contact manner, in the state where the adsorption unit 60 and the friction holding unit 70 hold the back surface Wb. As illustrated in FIG. 3, the first fork portion 12 is provided with, for example, a plurality of non-contact holding units 80. When the plurality of non-contact holding units 80 are provided, the plurality of non-contact holding units 80 may have the same configuration. For example, each non-contact holding unit 80 injects air into the space between the back surface Wb of the substrate W and the non-contact holding unit 80, to hold the back surface Wb in the non-contact manner by suction. The non-contact holding unit 80 may suck the back surface Wb, such that a downward force acts on the back surface Wb.

An air injection hole may be formed at the upper end of the non-contact holding unit 80, and the non-contact holding unit 80 may inject air from the injection hole such that a swirling flow is formed between the back surface Wb and the non-contact holding unit 80. When the swirling flow is formed, a negative pressure is generated in the vicinity of the injection hole, and the back surface Wb is sucked by the negative pressure. Instead of the swirling flow, the non-contact holding unit 80 may inject air in a radial direction from the injection hole. When air is injected in the radial direction, a negative pressure is generated by the Bernoulli effect, and the back surface Wb is sucked by the negative pressure.

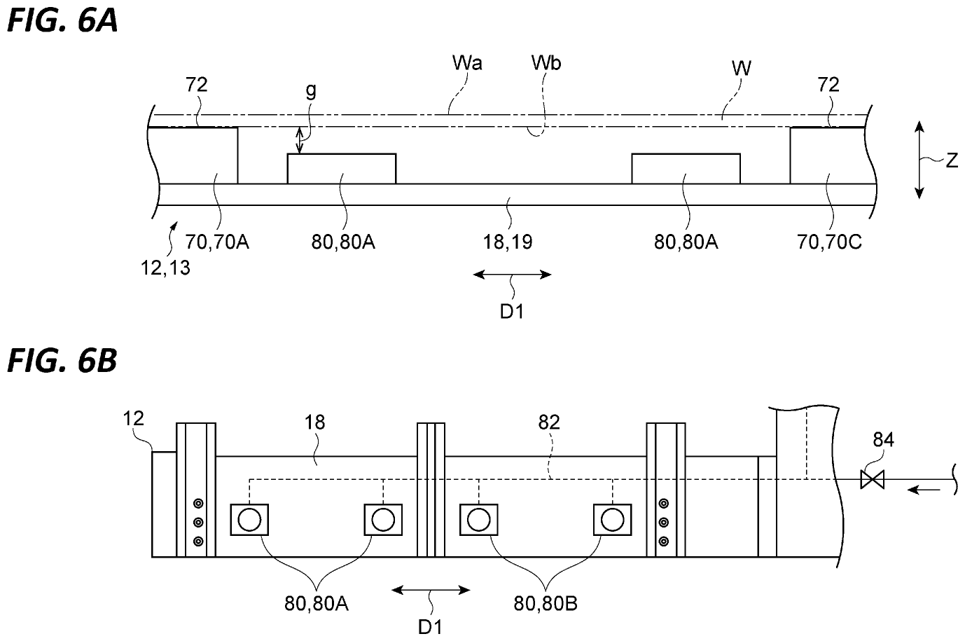

The non-contact holding unit 80 may be fixed to a predetermined position on the hand 10. The non-contact holding unit 80 is fixed to, for example, the body portion 18 of the first fork portion 12, and the relative position thereof to the body portion 18 does not vary. When the substrate W is supported by the hand 10, the adsorption unit 60 may contract such that the back surface Wb approaches the non-contact holding unit 80. In the state where the adsorption unit 60 contracts so that the back surface Wb comes into contact with the upper end of the friction holding unit 70, a gap “g” is formed between the upper end of the non-contact holding unit 80 and the back surface Wb as illustrated in FIG. 6A. Since the non-contact holding unit 80 is fixed, the gap “g” is substantially constant when each of the plurality of substrates W is supported.

The substrate transfer robot 2 includes an air supply path 82 and an open/close valve 84, as illustrated in FIG. 6B. The air supply path 82 is a flow path that connects each of the plurality of non-contact holding units 80 and an air supply pump provided in the substrate transfer system 1. The air supply pump sends out, for example, compressed air to each of each non-contact holding unit 80 through the air supply path 82. At least a portion of the air supply path 82 may be provided inside the body portion 18 of the first fork portion 12.

The open/close valve 84 switches the open/close states of the air supply path 82. When the open/close valve 84 is in the open state, each of the plurality of non-contact holding units 80 and the air supply pump are connected, so that each non-contact holding unit 80 may suck the back surface Wb in the non-contact manner. When the open/close valve 84 is in the closed state, the connection between each of the plurality of non-contact holding units 80 and the air supply pump are shut off, so that each non-contact holding unit 80 does not suck the back surface Wb.

Referring back to FIG. 3, at least some of the non-contact holding units 80 may hold the region between the region of the back surface Wb held by any one adsorption unit 60 (first region) and the region of the back surface Wb held by any one adsorption unit 60 (second region), in the direction D1. At least some of the non-contact holding units 80 may hold the region between the region of the back surface Wb held by any one friction holding unit 70 (first region) and the region of the back surface Wb held by any one friction holding unit 70, in the direction D1. At least some of the non-contact holding units 80 may hold the region between the region of the back surface Wb held by any one adsorption unit 60 (first or second region) and the region of the back surface Wb held by any one friction holding unit 70 (second or first region), in the direction D1. The region of the back surface Wb held by each holding unit (a portion of the regions) refers to the region where each holding unit and the back surface Wb overlap with each other when viewed from above.

In the example illustrated in FIG. 3, four non-contact holding units 80 are provided on the body portion 18 of the first fork portion 12. In an example, two of the four non-contact holding units 80 hold one of the pair of regions IA arranged in the direction D1, which is far from the base portion 11, in the non-contact manner. The remaining two non-contact holding units 80 hold the other of the pair of regions IA, which is close to the base portion 11, in the non-contact manner.

In FIG. 3, “80A” indicates the two non-contact holding units 80 that hold the region IA far from the base portion 11, and “80B” indicates the two non-contact holding units 80 that hold the region IA close to the base portion 11. The two non-contact holding units 80A and the two non-contact holding units 80B may be arranged side by side along the direction D1, or may be arranged at the same position in the direction D2.

The non-contact holding units 80A hold the region between the region of the back surface Wb held by the adsorption unit 60A (first region) and the region of the back surface Wb held by the friction holding unit 70C (third region), in the direction D1. The non-contact holding units 80A hold the region between the region of the back surface Wb held by the friction holding unit 70A (first region) and the region of the back surface Wb held by the friction holding unit 70C (third region), in the direction D1.

The non-contact holding units 80B (second non-contact holding units) hold the region between the region of the back surface Wb held by the friction holding unit 70C (third region) and the region of the back surface Wb held by the adsorption unit 60B (second region), in the direction D1. The non-contact holding units 80B hold the region between the region of the back surface Wb held by the friction holding unit 70C (third region) and the region of the back surface Wb held by the friction holding unit 70B (second region), in the direction D1.

The arrangement (layout) of the three types of holding units illustrated in FIG. 3, including the adsorption units 60, the friction holding units 70, and the non-contact holding units 80, and the number of the holding units are examples and may be appropriately changed. Instead of or in addition to the friction holding unit 70C, the adsorption unit 60 may hold a portion of the region PA2 (third region). At each end of the back surface Wb in the direction D1, the friction holding unit 70 may not be disposed, and instead, one or more of the adsorption units 60 may hold the ends, or the adsorption units 60 may not be disposed, and instead, one or more friction holding units 70 may hold the end.

Each of both ends of the back surface Wb in the direction D1 may be held by either one of the adsorption unit 60 and the friction holding unit 70, or by both the adsorption unit 60 and the friction holding unit 70, and the region between both the ends may be held by one or more non-contact holding units 80 rather than the adsorption unit 60 and the friction holding unit 70. Instead of both the ends of the back surface Wb in the direction D1, the portion located inside each of both the ends may be held by either one of the adsorption unit 60 and the friction holding unit 70, or by both the adsorption unit 60 and the friction holding unit 70.

Similar to the first fork portion 12, the second fork portion 13 includes one or more adsorption units 60, one or more friction holding units 70, and one or more non-contact holding units 80. The arrangement (layout) of the three types of holding units in the second fork unit 13 may be line symmetrical with the arrangement in the first fork unit 12 with respect to a virtual line passing through the center between the first fork unit 12 and the second fork unit 13 and extending in the direction D1.

In the second fork unit 13 as well, a vacuum pump may be connected to each of the plurality of adsorption units 60 via the suction path 62, and an air supply pump may be connected to each of the plurality of non-contact holding units 80 via the air supply path 82. In this case, when the open/close valve 64 is in the open state, the plurality of adsorption units 60 of the first fork portion 12 and the plurality of adsorption units 60 of the second fork portion 13 may be able to adsorb the back surface Wb. When the open/close valve 84 is in the open state, the plurality of non-contact holding units 80 of the first fork portion 12 and the plurality of non-contact holding units 80 of the second fork portion 13 may be able to suck the back surface Wb in the non-contact manner. Instead of sharing the flow path, the suction path 62 and the open/close valve 64 may be provided separately, and the air supply path 82 and the open/close valve 84 may be provided separately, in each of the first fork portion 12 and the second fork portion 13.

### <Pressure Sensor>

The substrate transfer robot 2 includes a pressure sensor 92 as illustrated in FIG. 4B. The pressure sensor 92 detects the pressure of the suction path 62 connected to the adsorption units 60. The pressure sensor 92 may output a signal when the pressure of the suction path 62 becomes a predetermined level or more, or output an electrical signal corresponding to a pressure value of the suction path 62. In the case where the suction path 62 is connected to the plurality of adsorption units 60, the pressure sensor 92 may be disposed in a flow path of the suction path 62 other than each branched suction path 62 (common flow path).

When the opening of the upper end of one adsorption unit 60 is not blocked by the back surface Wb, the pressure of the suction path 62 does not increase even when the open/close valve 64 is in the open state. Thus, the state of the operation of the adsorption unit 60 on the back surface Wb may be identified by a detection result from the pressure sensor 92. When the suction path 62 and the open/close valve 64 are provided separately, the pressure sensor 92 is also provided separately in each of the first fork portion 12 and the second fork portion 13. The pressure sensor 92 outputs a signal indicating the result of detecting the pressure of the suction path 62, to the robot controller 100.

### <Load Presence Sensor>

The substrate transfer robot 2 has a load presence sensor 94 as illustrated in FIG. 3. The load presence sensor 94 detects the substrate W on the hand 10. For example, the load presence sensor 94 generates different signals and outputs the signals to the robot controller 100 for the case where the substrate W is present on the hand 10 and the case where the substrate W is not present on the hand 10. The load presence sensor 94 may be any type of sensor as long as it is capable of detecting the substrate W, and is, for example, a photoelectric sensor. The load presence sensor 94 may be provided on each of the body portion 18 of the first fork portion 12 and the body portion 19 of the second fork portion 13.

### (Robot Controller)

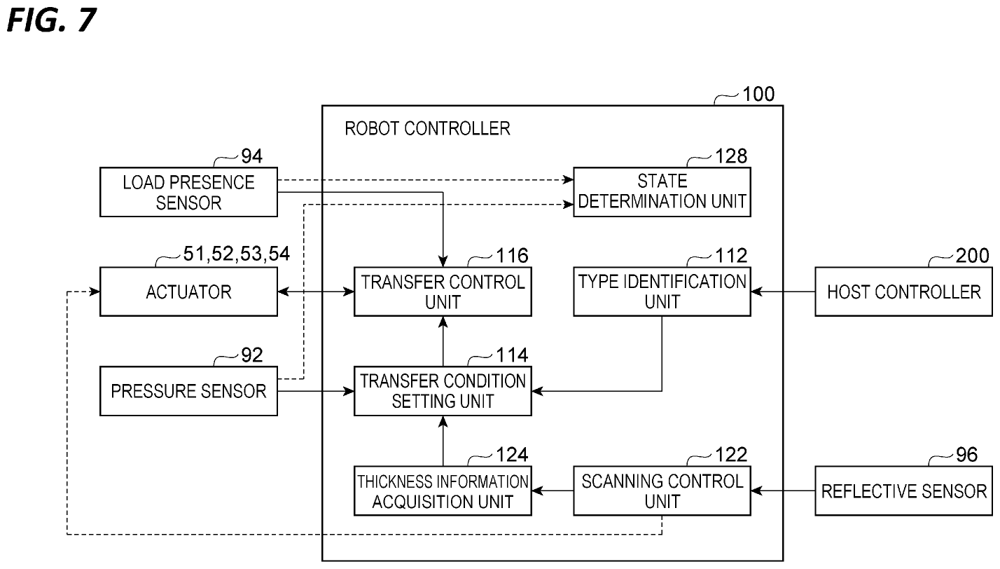

The robot controller 100 is a computer that controls the substrate transfer robot 2. FIG. 7 illustrates an example of the functional configuration of the robot controller 100. The robot controller 100 includes a type identification unit 112, a transfer condition setting unit 114, and a transfer control unit 116, as functional components (hereinafter, referred to as “functional blocks”).

The type identification unit 112 identifies the type of the substrate W to be processed (to be transferred) from a plurality of workpiece types. For example, the type identification unit 112 identifies the type of the substrate W to be processed, based on information from a host controller 200. The host controller 200 sends, for example, a command for executing the transfer of the substrate W to the robot controller 100. The plurality of workpiece types include a first type of workpiece and a second type of workpiece. The second type of workpiece is a workpiece with a larger mass than the first type of workpiece.

As compared to a substrate W with a small mass, a substrate W with a large mass has the significant inertia during the transfer, and thus, tends to easily deviate from the hand 10 when the holding force acting on the substrate W is weak. In an example, the plurality of types of substrates W to be processed by the substrate transfer system 1 are classified into the two types including the first type of workpiece and the second type of workpiece. The first type of workpiece may include one or more types of substrates W each having the mass in a first range, and the second type of workpiece may include one or more types of substrates W each having the mass in a second range larger than the first range. When the thicknesses and the masses of the substrates W among the plurality of workpiece types have a correlation (e.g., a proportional relationship), the size relationship of the masses of the substrates W may be estimated by the size relationship of the thicknesses of the substrates W. In this case, the second type of workpiece may have a larger thickness than that of the first type of workpiece.

The transfer condition setting unit 114 sets a transfer condition for transferring the substrate W to be processed, based on the detection result from the pressure sensor 92. The transfer condition set by the transfer condition setting unit 114 is a condition that may be adjusted to reduce the inertia of the substrate W during the transfer. For example, the transfer condition setting unit 114 sets a transfer speed for transferring the substrate W, as the transfer condition, based on the detection result from the pressure sensor 92.

In an example, the transfer condition setting unit 114 may set the transfer speed to a reference value when the pressure of the suction path 62 is larger than the predetermined level, and may set the transfer speed to a value smaller than the reference value when the pressure of the suction path 62 is smaller than the predetermined level. The transfer condition setting unit 114 may determine the size relationship between the pressure of the suction path 62 and the predetermined level, based on the presence/absence of a signal from the pressure sensor 92 indicating that the pressure of the suction path 62 exceeds the predetermined level, or a result of a comparison between a value of the pressure detected by the pressure sensor 92 and the predetermined level.

In the case where the suction path 62 is provided separately in each of the first fork portion 12 and the second fork portion 13, the transfer condition setting unit 114 may determine that the pressure of the suction path 62 is smaller than the predetermined level when the pressure in the suction path 62 of any one of the fork portions is smaller than the predetermined level. In the robot controller 100, the reference value of the transfer speed may be stored in advance. The reference value of the transfer speed may vary for each section in which the substrate W is transferred. When the transfer speed is set to a value smaller than the reference value, the transfer condition setting unit 114 may set the transfer speed to a value smaller than the reference value corresponding to each section.

The transfer condition setting unit 114 may set the transfer speed based on an identification result from the type identification unit 112, in addition to the detection result from the pressure sensor 92. In an example, when the pressure of the suction path 62 is larger than the predetermined level above, the transfer condition setting unit 114 sets the transfer speed to the reference value, regardless of the identification result from the type identification unit 112. When the pressure of the suction path 62 is larger than the predetermined level above, it is assumed that each adsorption unit 60 is reliably adsorbing (holding) the back surface Wb, and therefore, the processing target substrate W may be transferred at the transfer speed set to the reference value.

Meanwhile, when the pressure of the suction path 62 is smaller than the predetermined level above, the transfer condition setting unit 114 sets the transfer speed according to the type of the processing target substrate W. When the pressure of the suction path 62 is smaller than the predetermined level above, and the type of the processing target substrate W is identified as the first type of workpiece by the type identification unit 112, the transfer condition setting unit 114 may set the transfer speed to a first value equal to or smaller than the reference value. The first value may be the same as the reference value. When the pressure of the suction path 62 is smaller than the predetermined level, and the type of the substrate W is identified as the second type of workpiece by the type identification unit 112, the transfer condition setting unit 114 may set the transfer speed to a second value smaller than the first value.

The transfer control unit 116 controls the substrate transfer robot 2 to transfer the processing target substrate W while supporting the substrate W on the hand 10. For example, the transfer control unit 116 controls the substrate transfer robot 2 to transfer the processing target substrate W between the cassette 190 and the predetermined position distant from the cassette 190 (e.g., a predetermined position in the substrate processing apparatus). The operation of the substrate transfer robot 2 may be predetermined according to each of the slots 193 of the cassette 190 in which the processing target substrate W is being placed or is to be placed. The transfer control unit 116 may control the actuators 51, 52, 53, and 54 included in the substrate transfer robot 2 according to the transfer condition (e.g., the transfer speed) set by the transfer condition setting unit 114.

The transfer control unit 116 may perform a control such that the adsorption of the substrate W by each adsorption unit 60 and the suction of the substrate W by each non-contact holding unit 80 start after the hand 10 starts supporting the processing target substrate W (after the substrate W is placed on the hand 10). For example, after the hand 10 starts supporting the processing target substrate W, the transfer control unit 116 switches the open/close valve 64 that opens/closes the suction path 62 connected to each adsorption unit 60 from the close state to the open state, and the open/close valve 84 that opens/closes the air supply path 82 connected to each non-contact holding unit 80 from the close state to the open state. When the adsorption by the adsorption units 60 and the suction by the non-contact holding units 80 act on the substrate W after the hand 10 starts supporting the processing target substrate W, forces such as the suction force act on the back surface Wb of the substrate W in the state where the substrate W is being supported by, for example, the substrate support units 192, so that the warping or deformation of the substrate W may be avoided. The timing for starting the adsorption by the adsorption units 60 and the suction by the non-contact holding units 80 is not limited to the example described above. For example, in a case where the hand 10 is positioned below the substrate W supported by the substrate support units 192, and then, moved up to load the substrate W thereon, the transfer control unit 116 may start the adsorption of the substrate W by each adsorption unit 60 and the suction of the substrate W by each non-contact holding unit 80 after the start of the upward movement of the hand 10.

The transfer control unit 116 may control the substrate transfer robot 2 to transfer the substrate W when the substrate W is detected by the load presence sensor 94, and may stop the transfer operation of the substrate W by the substrate transfer robot 2 when no substrate W is detected by the load presence sensor 94. For example, the transfer control unit 116 continues the transfer operation of the substrate W by the hand 10 when the substrate W is detected by the load presence sensor 94 after the hand 10 performs the operation to start supporting the processing target substrate W. Meanwhile, the transfer control unit 116 stops the transfer operation of the substrate W by the hand 10 when no substrate W is detected by the load presence sensor 94 for a certain reason after the hand 10 performs the supporting operation (stop for abnormality).

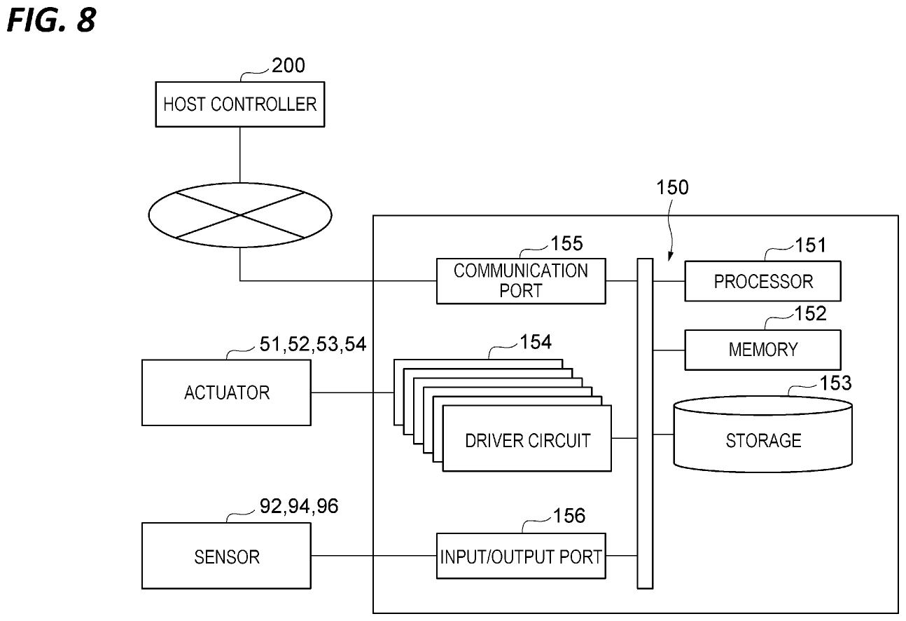

FIG. 8 illustrates an example of the hardware configuration of the robot controller 100. The robot controller 100 includes a circuit 150. The circuit 150 includes a processor 151, a memory 152, a storage 153, a driver circuit 154, and a communication port 155. The storage 153 includes one or more nonvolatile memory devices such as a flash memory and a hard disk. The storage 153 stores a program that causes the robot controller 100 to control the substrate transfer robot 2 such that the substrate W is transferred in the state where each of the adsorption units 60, the friction holding units 70, and the non-contact holding units 80 holds the back surface Wb. For example, the storage 153 stores a program that causes the robot controller 100 to be configured with the functional blocks described above.

The memory 152 includes one or more volatile memory devices such as, for example, a random access memory. The memory 152 temporarily stores the program loaded from the storage 153. The processor 151 is configured with one or more calculation devices such as a central processing unit (CPU) or a (graphics processing unit (GPU). The processor 151 causes the robot controller 100 to be configured with the functional blocks described above by executing the program loaded into the memory 152. The result of the calculation by the processor 151 is temporarily stored in the memory 152.

The diver circuit 154 operates the actuators 51, 52, 53, and 54 of the substrate transfer robot 2 in response to a request from the processor 151. The communication port 155 communicates with the host controller 200 in response to a request from the processor 151. The input/output port 156 inputs/outputs information to/from sensors such as the pressure sensor 92 and the load presence sensor 94 in response to a request from the processor 151.

### [Substrate Transfer Method]

Next, as an example of a substrate transfer method, a transfer process performed in the substrate transfer system 1 will be described. The transfer process (substrate transfer method) is a process in which the substrate W is transferred by the substrate transfer robot 2 provided with the hand 10, and includes controlling the substrate transfer robot 2 to transfer the substrate W in the state where each of the adsorption units 60, the friction holding units 70, and the non-contact holding units 80 hold the back surface Wb.

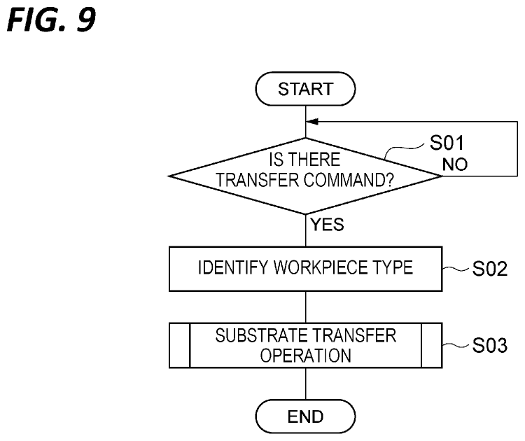

Next, FIG. 9 illustrates a series of processes performed by the robot controller 100 during the transfer process. In the series of processes, the processing target substrate W is transferred from the cassette 190 to the predetermined position by the substrate transfer robot 2 according to a transfer command from the host controller 200. First, the robot controller 100 performs step S01. In step S01, for example, the robot controller 100 waits until receiving the transfer command from the host controller 200. The transfer command from the host controller 200 may include information indicating the type of the processing target substrate W and a slot 193 in which the processing target substrate W is being placed in the cassette 190.

Next, the robot controller 100 performs step S02. In step S02, for example, the type identification unit 112 identifies the type of the processing target substrate W based on the information included in the transfer command from the host controller 200. In an example, the type identification unit 112 identifies whether the processing target substrate W is the first type of workpiece or the second type of workpiece having the larger mass (or thickness) than that of the first type of workpiece.

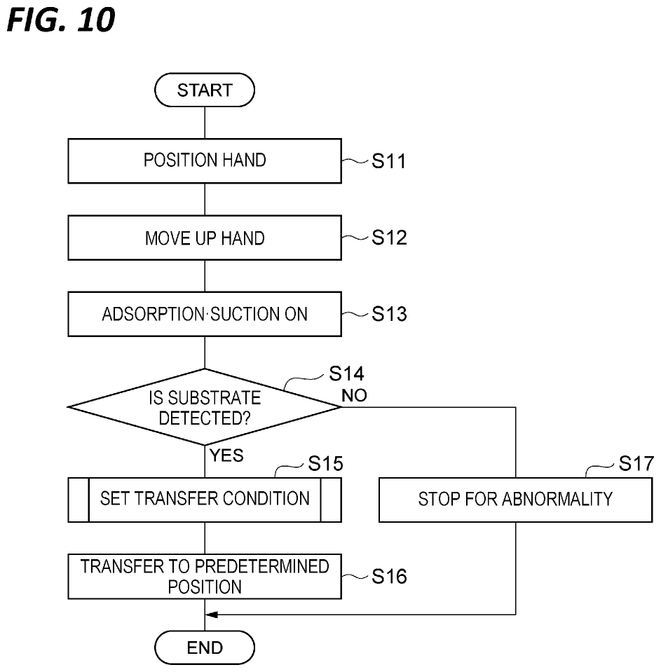

Next, the robot controller 100 performs step S03. In step S03, for example, the transfer control unit 116 controls the substrate transfer robot 2 to receive the processing target substrate W in the cassette 190 by the hand 10 and transfer the substrate W supported on the hand 10 to the predetermined position. FIG. 10 illustrates a series of processes performed by the robot controller 100 in step S03.

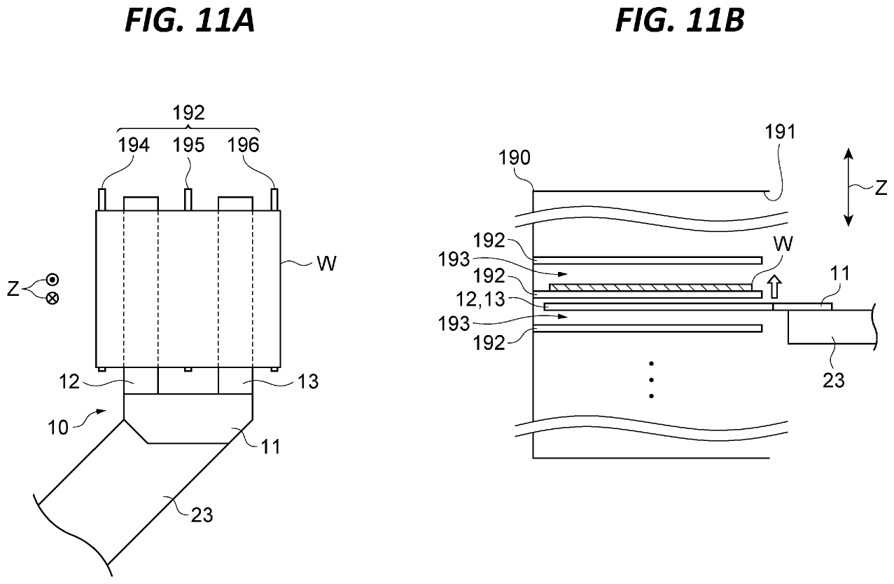

In step S03, first, the robot controller 100 performs step S11. In step S11, for example, the transfer control unit 116 controls the multi-joint arm 20 such that the first fork portion 12 and the second fork portion 13 of the hand 10 are positioned vertically below the processing target substrate W in the cassette 190, as illustrated in FIG. 11A. FIG. 11A omits the illustration of the housing of the cassette 190, and illustrates one substrate support unit 192 that supports the processing target substrate W.

The transfer control unit 116 may control the multi-joint arm 20 such that the hand 10 is positioned in a slot 193 directly below the slot 193 in which the processing target substrate W is being placed, as illustrated in FIG. 11B. The transfer control unit 116 may move the hand 10 by the multi-joint arm 20 such that when viewed from above, each of the one or more adsorption units 60, the one or more friction holding units 70, and the one or more non-contact holding units 80 overlaps with the location (region) of the back surface Wb that will be held.

Next, the robot controller 100 performs step S12. In step S12, for example, the transfer control unit 116 controls the actuator 54 of the multi-joint arm 20 to move up the hand 10. In an example, the transfer control unit 116 moves up the hand 10 by the actuator 54, by a predetermined amount, to load the substrate W on the hand 10.

Next, the robot controller 100 performs step S13. In step S13, for example, the transfer control unit 116 controls the substrate transfer robot 2 to start the adsorption by the adsorption units 60 and the suction by the non-contact holding units 80. The transfer control unit 116 may switch the open/close valve 64 provided in the suction path 62 from the close state to the open state, and the open/close valve 84 provided in the air support path 82 from the close state to the open state. In an example, as the hand 10 supports the substrate W according to step S12 (due to the weight of the substrate W itself) or as the adsorption by each adsorption unit 60 starts, the adsorption unit 60 contracts, and as a result, the back surface Wb of the processing target substrate W comes into the contact with the holding surface 72 positioned at the upper end of the friction holding unit 70. As long as a trouble does not occur resulting from a certain cause, each of the adsorption units 60, the friction holding units 70, and the non-contact holding units 80 is in the state of holding the back surface Wb of the substrate W after the performance of step S13.

Next, the robot controller 100 performs step S14. In step S14, for example, the transfer control unit 116 determines whether the processing target substrate W is being supported on the hand 10, based on the detection result from the load presence sensor 94. When it is determined in step S14 that the substrate W is being supported on the hand 10 (step S14: YES), the process performed by the robot controller 100 proceeds to step S15.

In step S15, for example, the transfer condition setting unit 114 sets the transfer speed as the transfer condition. The details of step S15 will be described later. Next, the robot controller 100 performs step S16. In step S16, for example, the transfer control unit 116 controls the multi-joint arm 20 to transfer the processing target substrate W according to the transfer speed set in step S15. By performing step S16, the processing target substrate W is transferred from the cassette 190 to the predetermined position, and the transfer process for one substrate W is completed.

Meanwhile, when it is determined in step S14 that no substrate W is being supported on the hand 10 (step S14: NO), the process performed by the robot controller 100 proceeds to step S17. When the receiving of the processing target substrate W from the substrate support unit 192 by the hand 10 is not appropriately performed for a certain reason, the substrate W on the hand 10 may not be detected by the load presence sensor 94. In step S17, for example, the robot controller 100 stops the transfer operation of the processing target substrate W for the reason of abnormality. The robot controller 100 may output a signal indicating the stop for abnormality to the host controller 200, or inform an operator or other workers of the stop for abnormality.

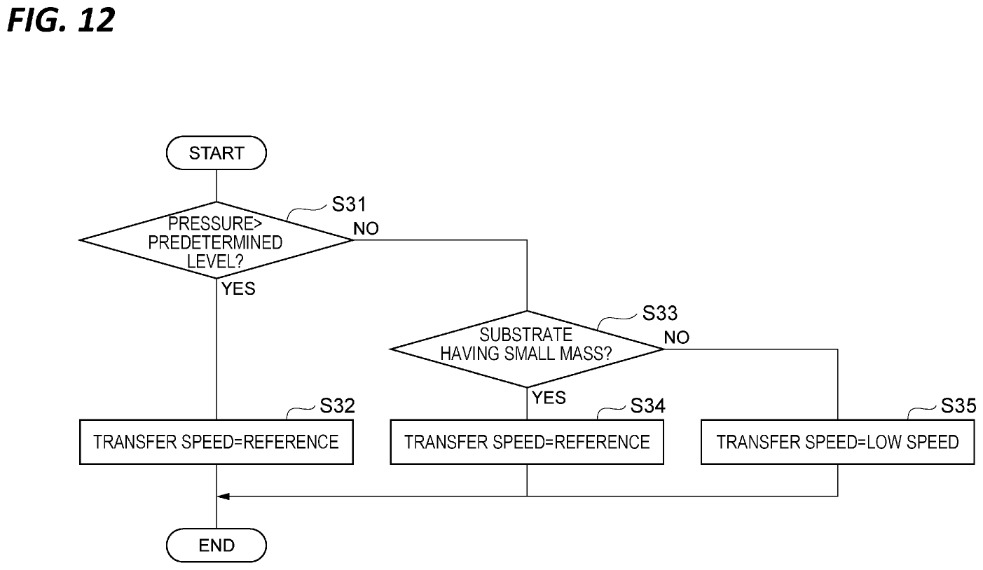

FIG. 12 illustrates a series of processes performed in step S15. In order to set the transfer speed in step S15, first, the robot controller 100 performs step S31. In step S31, for example, the transfer condition setting unit 114 determines whether the pressure value detected by the pressure sensor 92 (the value indicating the pressure of the suction path 62) is larger than the predetermined level. The predetermined level may be preset to a value at which it may be determined that the adsorption by the adsorption units 60 is acting on the substrate W when the pressure value is larger than the level.

When it is determined in step S31 that the pressure value detected by the pressure sensor 92 is larger than the predetermined level above (step S31: YES), the process performed by the robot controller 100 proceeds to step S32. In step S32, for example, the transfer condition setting unit 114 sets the transfer speed to the reference value.

Meanwhile, when it is determined in step S31 that the pressure value detected by the pressure sensor 92 is equal to or smaller than the predetermined level above (step S31: NO), the process performed by the robot controller 100 proceeds to step S33. In step S33, for example, the transfer condition setting unit 114 determines whether the type of the processing target substrate W identified by the type identification unit 112 in step S02 is the first type of workpiece having the small mass (or thickness).

When it is determined in step S33 that the type of the processing target substrate Wis the first type of workpiece (step S33: YES), the process performed by the robot controller 100 proceeds to step S34. In step S34, for example, the transfer condition setting unit 114 sets the transfer speed to the reference value (first value) as in step S32.

Meanwhile, when it is determined in step S33 that the type of the processing target substrate W is not the first type of workpiece (step S33: NO), the process performed by the robot controller 100 proceeds to step S35. In step S35, for example, the transfer condition setting unit 114 sets the transfer speed to a value smaller than the reference value (second value). In this way, the transfer speed is set according to the the result of the detection of the pressure in the suction path 62 and the result of the determination as to the type of the processing target substrate W.

The robot controller 100 may repeat the series of processes of steps S01 to S03 that perform the transfer operation of the processing target substrate W, according to the transfer command from the host controller 200.

### Modifications

The series of processes illustrated in each of FIGS. 9, 10, and 12 are examples, and may be appropriately modified. In the series of processes, the robot controller 100 may perform one step and the subsequent step in parallel, or may perform the steps in a different order from that in the examples described above. The robot controller 100 may omit any one of the steps, and may perform a different process in any one of the steps from that in the examples.

During step S12, the robot controller 100 may perform step S13. During step S12, the robot controller 100 may perform step S13 after the substrate W is loaded on the hand 10 from the substrate support unit 192 and before the upward movement of the hand 10 is stopped. Step S02 may be performed during the series of processes in step S15. The transfer condition setting unit 114 may set the transfer speed to the first value smaller than the reference value in step S34, and may set the transfer speed to the second value smaller than the first value in step S35.

When the pressure of the suction path 62 is equal to or smaller than the predetermined level, the robot controller 100 may set the transfer speed based on information indicating the thickness of the processing target substrate W, instead of the type of the processing target substrate W. Since the mass of the substrate W may be estimated by the thickness of the substrate W as described above, the transfer speed may be set based on the information indicating the thickness of the substrate W, so that the inertia acting on the substrate W during the transfer may be adjusted. As illustrated in FIG. 3, the substrate transfer robot 2 may include a reflective sensor 96. The reflective sensor 96 may be provided at the distal end of each of the first fork portion 12 and the second fork portion 13 of the hand 10.

The reflective sensor 96 is capable of detecting each of the plurality of substrates W in the state of being accommodated in the cassette 190. For example, the reflective sensor 96 emits a laser beam in the horizontal direction, and receives a reflective light reflected back from an object. The reflective light returning to the reflective sensor 96 varies according to the presence/absence of an object in the emitting direction of the laser beam, or the distance from the reflective sensor 96 to the object. Therefore, the presence and position of an object may be detected based on the reflective light received by the reflective sensor 96.

As illustrated in FIG. 7, the robot controller 100 may include a scanning control unit 122 and a thickness information acquisition unit 124. The scanning control unit 122 acquires a detection result from the reflective sensor 96 when the hand 10 is moved in the vertical direction. The scanning control unit 122 repeatedly acquires the reflective light by the reflective sensor 96 while moving the hand 10 from downward to upward or from upward to downward along the multi-tire slots 193 in the cassette 190. The scanning control unit 122 associates the height position of the reflective sensor 96 on the hand 10 with the reflective light obtained at the height position. As a result, the robot controller 100 may identify the slot 193 in which the substrate W is being placed in the cassette 190.

The thickness information acquisition unit 124 acquires the thickness of the substrate W. The thickness information acquisition unit 124 may measure the thickness of the substrate W by using the detection result from the reflective sensor 96. In an example, the thickness information acquisition unit 124 acquires the thickness of the substrate W based on the detection result from the reflective sensor 96 when the hand 10 is moved in the vertical direction. That is, from the information obtained for detecting the plurality of substrates W in the cassette 190 using the reflective sensor 96, the thickness information acquisition unit 124 may acquire (measure) the thickness of each of the plurality of detected substrates W.

The transfer condition setting unit 114 may set the transfer speed as the transfer condition for the processing target substrate W, based on an acquisition result from the thickness information acquisition unit 124, in addition to the detection result from the pressure sensor 92. In an example, when the pressure of the suction path 62 is larger than a first predetermined level, the transfer condition setting unit 114 sets the transfer speed to the reference value, regardless of the acquisition result from the thickness information acquisition unit 124. The first predetermined level is the same as the predetermined level for the pressure of the suction path 62 described above. When the pressure of the suction path 62 is smaller than the first predetermined level, the transfer condition setting unit 114 sets the transfer speed according to the information indicating the thickness of the substrate W acquired by the thickness information acquisition unit 124.

In an example, when the pressure of the suction path 62 is smaller than the first predetermined level above, and the thickness of the substrate W is smaller than a second predetermined level, the transfer condition setting unit 114 sets the transfer speed to the first value equal to or smaller than the reference value. The second predetermined level is set to a thickness at which the substrate W may be transferred while being held by the hand 10 without significantly reducing the transfer speed (e.g., even when the transfer speed is set to the reference value), even though the adsorption by the adsorption unit 60 does not act on the substrate W. The second predetermined level may be stored in advance in the robot controller 100. When the pressure of the suction path 62 is smaller than the first predetermined level, and the thickness of the substrate W is larger than the second predetermined level, the transfer condition setting unit 114 sets the transfer speed to the second value smaller than the first value.

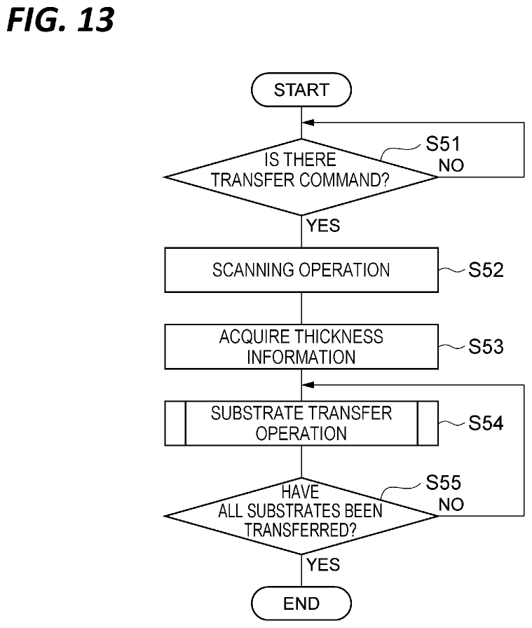

FIG. 13 illustrates a series of processes performed by the robot controller 100 when the transfer speed is set based on the information indicating the thickness of the substrate W. First, the robot controller 100 performs step S51. In step S51, for example, the robot controller 100 waits to receive a transfer command from the host controller 200. The transfer command from the host controller 200 may include a command to start the transfer of the processing target substrate W in the cassette 190 without including the position of the substrate W, the number of substrates W, and the type of the substrate W.

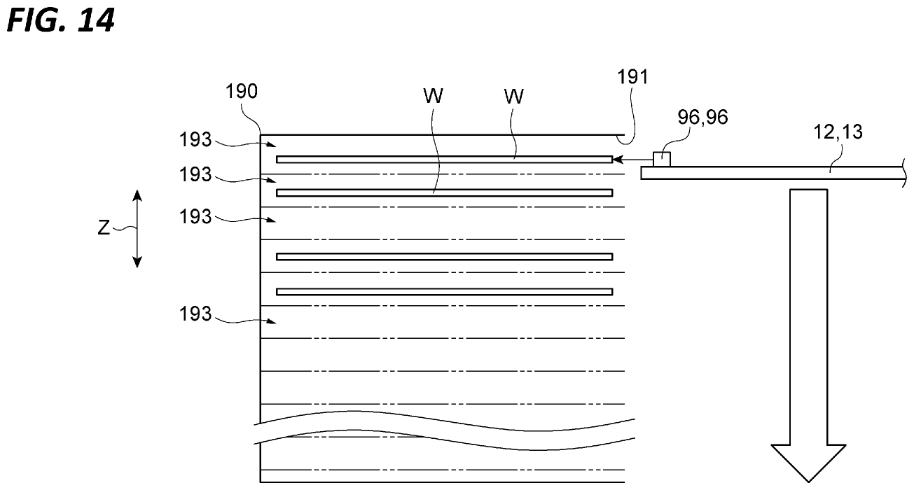

Next, the robot controller 100 performs step S52. In step S52, for example, the scanning control unit 122 controls the substrate transfer robot 2 to move along the vertical direction while causing the reflective sensor 96 to be directed toward the cassette 190, as illustrated in FIG. 14. The scanning control unit 122 may control the multi-joint arm 20 to make the reflective sensor 96 face the uppermost slot 193 in the cassette 190 from the outside of the opening 191 in the direction orthogonal to the opening 191, and then, move down the reflective sensor 96 until the reflective sensor 96 faces the lowermost slot 193 in the cassette 190. The scanning control unit 122 may detect whether the substrate W is being supported in each of the multi-tier slots 193, based on the reflective light obtained by moving down the reflective sensor 96.

Next, the robot controller 100 performs step S53. In step S53, for example, the thickness information acquisition unit 124 measures the thickness of each of the plurality of substrates W accommodated in the cassette 190 based on the detection result obtained from the reflective sensor 96 in step S52. In step S52, the emission of the laser beam from the reflective sensor 96 may be repeated while the reflective sensor 96 is moved up and down, to the extent that the thickness of the substrate W may be measured.

Next, the robot controller 100 performs step S54. The robot controller 100 may perform step S54 in the same manner as that in the series of processes illustrated in FIG. 10, except for some process details. When positioning the hand 10 in step S11, the transfer controller 116 sets, for example, the substrate W placed in the uppermost slot of the cassette 90 as the transfer target based on the detection result obtained in step S52, and positions the hand 10 below the substrate W by the multi-joint arm 20.

In step S15, the transfer condition setting unit 114 performs the same processes as those of steps S31, S32, S34, and S35 illustrated in FIG. 12. Instead of step S33, the transfer condition setting unit 114 determines whether the thickness of the processing target substrate W is smaller than the second predetermined level. When it is determined that the thickness of the processing target substrate W is smaller than the second predetermined level, the robot controller 100 performs step S34, and when it is determined that the thickness of the processing target substrate W is larger than the second predetermined level, the robot controller 100 performs step S35.

After performing step S54, the robot controller 100 performs step S55. In step S55, for example, the robot controller 100 determines whether the transfer of all of the substrates W detected in the cassette 190 has been completed. When it is determined in step S55 that the transfer of all of the substrates W has not been completed (step S55: NO), the process performed by the robot controller 100 returns to step S54. Then, the robot controller 100 performs step S54 after changing the processing target substrate W. Meanwhile, when it is determined in step S55 that the transfer of all of the substrates W has been completed (step S55: YES), the series of processes performed by the robot controller 100 are terminated.

The thickness information acquisition unit 124 may measure the thickness of the processing target substrate W by operating the reflective sensor 96 for the purpose of measuring the thickness, without using the detection result obtained from the reflective sensor 96 when the scanning operation is performed to detect the presence/absence of the substrate W in the cassette 190. The thickness information acquisition unit 124 may measure the thickness of the substrate W from a detection result from a detection unit (e.g., a camera) other than the reflective sensor 96, or may acquire information indicating the thickness of the processing target substrate W from the host controller 200. The type identification unit 112 may identify the type of the processing target substrate W, using the information indicating the thickness acquired by the thickness information acquisition unit 124.

In the various examples described above, the robot controller 100 controls the substrate transfer robot 2 based on the detection results from the pressure sensor 92 and the load presence sensor 94. However, the state of the holding of the substrate W by the hand 10 may be determined based on the detection results from the pressure sensor 92 and the load presence sensor 94. The robot controller 100 may include a state determination unit 128 as illustrated in FIG. 7. The state determination unit 128 determines the state of the holding by each of the adsorption units 60, the friction holding units 70, and the non-contact holding units 80, based on the detection results from the pressure sensor 92 and the load presence sensor 94.

Whether the adsorption by the adsorption unit 60 is acting (operating) on the back surface Wb of the substrate W may be determined according to whether the pressure of the suction path 62 with the pressure sensor 92 provided therein is larger than the predetermined level. When it is detected by the load presence sensor 94 that the substrate W is present on the hand 10, it may be presumed that the friction holding by the friction holding units 70 and the suction by the non-contact holding units 80 are acting on the back surface Wb. The state determination unit 128 may determine that the holding by each of the adsorption units 60, the friction holding units 70, and the non-contact holding units 80 is acting on the back surface Wb, when the pressure of the suction path 62 is larger than the predetermined level, and the substrate W is detected by the load presence sensor 94.

When the pressure of the suction path 62 is smaller than the predetermined level, and the substrate W is detected by the load presence sensor 94, the state determination unit 128 may determine that the adsorption by the adsorption units 60 is not acting on the back surface Wb, and the holding by the friction holding units 70 and the non-contact holding units 80 is acting on the back surface Wb. When no substrate W is detected by the load presence sensor 94, the state determination unit 128 may determine that the holding by the adsorption units 60, the friction holding units 70, and the non-contact holding units 80 is not acting on the back surface Wb. Information indicating the result of the determination by the state determination unit 128 may be output to other devices, notified to the operator, or recorded in the robot controller 100.

When comparing the size relationship between two numerical values in the computer, any one of the two criteria “equal to or larger than” and “larger than” may be used, or any one of the two criteria “equal to or smaller than” and “smaller than” may be used. Selecting the criterion is not intended to change the technical significance of the process of comparing the size relationship of two numerical values. Any one of the various examples described above may be combined with at least a portion of the configurations described in the other examples.

### SUMMARY OF PRESENT DISCLOSURE

The present disclosure includes the configuration or method described in [1] to below.

[1] A substrate transfer robot 2 including: a hand 10 that supports a substrate W; and an arm 20 that operates the hand 10, wherein the hand 10 includes an adsorption unit 60 that holds a back surface Wb of the substrate W by adsorption, and is stretchable to lower a height position of an upper end thereof, a friction holding unit 70 that holds the back surface Wb by friction in a state where the adsorption unit 60 supporting the substrate W contracts, and a non-contact holding unit 80 that holds the back surface Wb in a non-contact manner, in a state where the adsorption unit 60 and the friction holding unit 70 hold the back surface Wb.

The back surface Wb of the substrate W may be set to have the contact region where contact is permitted, and the non-contact region where contact is not permitted. Since the hand 10 of the substrate transfer robot 2 described above is provided with the three types of holding units including two holding units that hold the back surface Wb in the contact manner and one holding unit that holds the back surface Wb in the non-contact manner, the force to hold the back surface Wb may be enhanced even though the contact region and the non-contact region are set. Further, since the friction holding unit 70 holds the back surface Wb by friction in the state the adsorption unit 60 contracts, it is possible to reduce the possibility that a gap occurs between the adsorption unit 60 and the back surface Wb in the case where the back surface Wb only comes into contact with the friction holding unit 70 without coming into the contact with the adsorption unit 60. Furthermore, the gap between the non-contact holding unit 80 and the back surface Wb is reduced by the contraction of the adsorption unit 60, so that the action on the back surface Wb such as the suction by the non-contact holding unit 80 is more reliably performed. Accordingly, the hand 10 may stably hold the substrate W, and then, transfer the substrate W. Therefore, the substrate transfer robot 2 is useful for stabilizing the transfer operation.

[2] The substrate transfer robot 2 described in [1] above, wherein in a state where the hand 10 is not supporting the substrate W, the height position H1 of the upper end of the adsorption unit 60 is higher than a height position H3 of an upper end of the friction holding unit 70, and in a state where the adsorption unit 60 contracts while adsorbing the back surface W, the back surface Wb comes into contact with the upper end of the friction holding unit 70.

When the height position of the upper end of the friction holding unit 70 is equal to or higher than the height position of the upper end of the adsorption unit 60 in the state where the hand 10 is not supporting the substrate W, the back surface Wb first comes into contact with the friction retainer 70, and does not come into contact with the adsorption unit 60, which may form a gap. When a gap occurs between the adsorption unit 60 and the back surface Wb, the adsorption by the adsorption unit 60 may hardly act on the back surface Wb. However, the configuration described above may reduce the possibility. Therefore, the substrate transfer robot 2 is useful for stabilizing the transfer operation.

[3] The substrate transfer robot 2 described in [1] or [2] above, wherein the adsorption unit 60 is able to contract from a first height position H1 to a second height position H2, and the upper end of the friction holding unit 70 is positioned between the first height position H1 and the second height position H2.

In this case, when the adsorption unit 60 supporting the substrate W contracts, the back surface Wb of the substrate W more securely comes into contact with the friction holding unit 70. Therefore, the substrate transfer robot 2 is useful for stabilizing the holding of the substrate W by the hand 10.

[4] The substrate transfer robot 2 described in any one of [1] to [3], wherein the non-contact holding unit 80 is fixed to a predetermined position on the hand 10, the adsorption unit 60 contracts such that the back surface Wb approaches the non-contact holding unit 80, when the substrate W is supported by the hand 10, and in a state where the adsorption unit 60 contracts to an extent that the back surface Wb comes into contact with the upper end of the friction holding unit 70, a gap “g” is formed between the upper end of the non-contact holding unit 80 and the back surface Wb.

In this case, the substrate W may be placed at the position where the holding by the non-contact holding unit 80 effectively acts by the contraction of the adsorption unit 60, even though the non-contact holding unit 80 itself is not moved in the hand 10. Therefore, the configuration of the non-contact holding unit 80 may be simplified. As a result, the substrate transfer robot 2 is useful for simplifying the hand 10.

[5] The substrate transfer robot 2 described in any one of [1] to [4], wherein the hand 10 includes one or more adsorption units 60 including the adsorption unit 60, and one or more friction holding units 70 including the friction holding unit 70, any one of the one or more adsorption units 60 or any one of the one or more friction holding units 70 holds a first region of the back surface Wb, any one of the one or more adsorption units 60 or any one of the one or more friction holding units 70 holds a second region of the back surface Wb arranged together with the first region along a predetermined direction D1, and the non-contact holding unit 80 holds a region between the first region and the second region in the predetermined direction D1.

In this case, the region between the pair of regions held in the contact manner in the back surface Wb may be held by the non-contact holding unit 80. Therefore, the substrate W may be stably transferred even though the non-contact region where contact is not permitted is set in the center of the back surface Wb.

[6] The substrate transfer robot 2 described in [5] above, wherein the hand 10 further includes a second non-contact holding unit 80 corresponding to the non-contact holding unit 80A, the first region is disposed at a first end of the back surface Wb in the predetermined direction D1, the second region is disposed at a second end of the back surface Wb opposite to the first end, and any one of the one or more adsorption units 60 or any one of the one or more friction holding units 70 holds a third region disposed between the first region and the second region in the predetermined direction D1, the non-contact holding unit 80A holds a region between the first region and the third region in the predetermined direction D1, and the second non-contact holding unit 80B holds a region between the third region and the second region in the predetermined direction D1.

In this case, each of the three regions of the back surface Wb arranged in the predetermined direction is held in the contact manner, and the region between adjacent regions of the three regions is held in the non-contact manner. Therefore, even though most of the central portion of the back surface Wb is the region where contact is not permitted, a portion of the central portion is also held in the contact manner. As a result, the substrate transfer robot 2 is useful for stabilizing the holding of the substrate W.

[7] The substrate transfer robot described in [6] above, wherein a first adsorption unit 60A of the one or more adsorption units 60 holds the first region disposed at the first end by adsorption, and a second adsorption unit 60B of the one or more adsorption units 60 holds the second region disposed at the second end by adsorption.

The degree to which the holding by the adsorption unit 60 acts on the back surface Wb tends to be larger than that by the friction holding unit 70 and the non-contact holding unit 80. In the configuration described above, since each of both ends of the back surface Wb is held by adsorption, it is possible to reduce the possibility that the substrate W is separated from the hand 10 during the transfer, especially at the ends of the back surface Wb. Therefore, the substrate transfer robot 2 is useful for stabilizing the holding of the substrate W.

[8] The substrate transfer robot 2 described in any one of [1] to [7] above, wherein the friction holding unit 70 includes a flat holding surface 72 that comes into contact with the back surface Wb when the adsorption unit 60 contracts, and the friction holding unit 70 is provided such that the holding surface 72 surrounds the adsorption unit 60.

In this case, even though the adsorption unit 60 is a contractible member, the back surface Wb is held by the holding surface 72 of the friction holding unit 70 that surrounds the adsorption unit 60. Therefore, the state where the adsorption unit 60 and the back surface Wb are in contact with each other is more easily maintained. As a result, the substrate transfer robot 2 is useful for stabilizing the holding of the substrate W.

[9] The substrate transfer robot 2 described in any one of [1] to [8] above, wherein the hand 10 includes a fork portion 12, the fork portion 12 is formed to extend in a predetermined direction D1, in a width direction D2 orthogonal to the predetermined direction D1, a width of the fork portion 12 is narrower than a width of the substrate W, the fork portion 12 includes the adsorption unit 60, the friction holding unit 70, and the non-contact holding unit 80, and in the width direction D2, a maximum width of the friction holding unit 70 is wider than a maximum width of a body portion 18 of the fork portion 12.

The wider the width of the friction holding unit 70, the stronger the holding force acting on the back surface Wb by the friction holding unit 70. However, when the size of the body portion 18 of the fork portion 12 is increased to correspond to the size of the friction holding unit 70, the size of the hand 10 increases. In the configuration described above, it is possible to achieve both the simplification (or weight reduction) of the hand 10 and the improvement of the holding force by friction.

[10] The substrate transfer robot 2 described in [9] above, wherein the hand 10 further includes a second fork portion 13 arranged while being spaced apart from the fork portion 12 in the width direction D2, and a portion of the friction holding unit 70 protrudes from the body portion 18 of the fork portion 12 in a space between the body portion 18 of the fork portion 12 and the second fork portion 13.

When a portion of the friction holding unit 70 protrudes from the body portion 18 in the opposite direction to the second fork portion 13, the entire size of the hand 10 in the width direction increases. In the configuration described above, the hand may be simplified while improving the holding force by friction.

[11] A substrate transfer system 1 including: the substrate transfer robot 2 described in any one of [1] to [10] above; a pressure sensor 92 that detects a pressure of a suction path 62 connected to the adsorption unit 60; a transfer control unit 116 that controls the substrate transfer robot to transfer the substrate W while supporting the substrate W on the hand 10; and a transfer condition setting unit 114 that sets a transfer condition for transferring the substrate W based on a detection result from the pressure sensor 92.

The state in which the adsorption by the adsorption unit 60 acts on the back surface Wb largely contributes to the state in which the substrate W is held on the entire hand 10. The state of the action by the adsorption unit 60 may be determined by the detection result of the pressure in the suction path 62. In the configuration described above, the transfer condition is set based on the detection result of the pressure in the suction path 62, so that the transfer condition may be set according to the state of the action by the adsorption unit 60. Therefore, the transfer of the substrate W may be stabilized.

[12] The substrate transfer system 1 described in [11] above, wherein the transfer condition setting unit 114 sets a transfer speed for transferring the substrate W as the transfer condition based on the detection result from the pressure sensor 92.

In the configuration above, the transfer speed may be set according to the state of the action by the adsorption unit 60. Therefore, the transfer of the substrate W may be further stabilized.

[13] The substrate transfer system 1 described in [13] above, wherein the transfer condition setting unit 114 sets the transfer speed to a reference value when the pressure of the suction path 62 is larger than a predetermined level, and sets the transfer speed to a value smaller than the reference value when the pressure of the suction path 62 is smaller than the predetermined level.

When the pressure of the suction path 62 is larger than the predetermined level, it may be determined that the state of the action by the adsorption unit 60 is adequate. Meanwhile, when the pressure of the suction path 62 is smaller than the predetermined level, it may be determined that the state of the action by the adsorption unit 60 is different from the adequate state. In the configuration described above, when the state of the action by the adsorption unit 60 is different from the adequate state, the transfer speed when transferring the substrate W decreases. Therefore, even when the holding force by the hand 10 is small, the substrate W is transferred at a low speed. As a result, it is possible to reduce the possibility that a problem will occur during the transfer.

[14] The substrate transfer system 1 described in [12] above, further including: a type identification unit 112 that identifies a type of the substrate from a plurality of workpiece types, wherein the transfer condition setting unit 114 further refers to an identification result from the type identification unit 112 in order to set the transfer speed.

Even when it is determined that the state of the action by the adsorption unit 60 is different from the adequate state, the transfer speed may not be significantly changed according to the type of the substrate W to be transferred. Thus, in the configuration described above, both the stabilization of the operation to transfer the substrate W and the throughput may be improved.

[15] The substrate transfer system 1 described in [14] above, wherein the plurality of workpiece types include a first type of workpiece and a second type of workpiece having a larger thickness or mass than that of the first type of workpiece, the transfer condition setting unit 114 sets the transfer speed to a reference value, regardless of the identification result from the type identification unit 112, when the pressure of the suction path 62 is larger than a predetermined level, sets the transfer speed to a first value equal to or smaller than the reference value, when the pressure of the suction path 62 is smaller than the predetermined level, and the type of the substrate is identified as the first type of workpiece, and sets the transfer speed to a second value smaller than the first value, when the pressure of the suction path 62 is smaller than the predetermined level, and the type of the substrate is identified as the second type of workpiece.

When the type of the substrate W to be transferred has a relatively small thickness or mass, the transfer speed may not be significantly reduced, even though it is determined that the state of the action by the adsorption unit 60 is different from the adequate state. Thus, in the configuration described above, both the stabilization of the operation to transfer the substrate W and the throughput may be achieved.

[16] The substrate transfer system 1 described in [12], further including: a thickness information acquisition unit 124 that acquires information indicating a thickness of the substrate, wherein the transfer condition setting unit 114 further refers to an acquisition result from the thickness information acquisition unit 124 in order to set the transfer speed.

Even when it is determined that the state of the action by the adsorption unit 60 is different from the adequate state, the transfer speed may not be significantly changed according to the thickness of the substrate W to be transferred. Thus, in the configuration above, both the stabilization of the operation to transfer the substrate W and the throughput may be improved.

[17] The substrate transfer system 1 described in [16] above, wherein the transfer condition setting unit 114 sets the transfer speed to a reference value, regardless of the acquisition result from the thickness information acquisition unit 124, when the pressure of the suction path 62 is larger than a first predetermined level, sets the transfer speed to a first value equal to or smaller than the reference value, when the pressure of the suction path 62 is smaller than the first predetermined level, and the thickness of the substrate W is smaller than a second predetermined level, and sets the transfer speed to a second value smaller than the first value, when the pressure of the suction path 62 is smaller than the first predetermined level, and the thickness of the substrate W is larger than the second predetermined level.

When the thickness of the substrate W to be transferred is small, the transfer speed may not be significantly reduced, even though it is determined that the state of the action by the adsorption unit 60 is different from the adequate state. Thus, in the configuration above, both the stabilization of the operation to transfer the substrate W and the throughput may be improved.

[18] The substrate transfer system 1 described in [16] or [17], further including: a cassette 190 that accommodates a plurality of substrates W including the substrate W, in a state of being arranged in a vertical direction; and a reflective sensor 96 provided on the hand 10 to detect each of the plurality of substrates W in a state of being accommodated in the cassette 190, wherein the thickness information acquisition unit 124 acquires the information indicating the thickness of the substrate W based on a detection result from the reflective sensor 96 when the hand 10 is moved in the vertical direction.

A scanning operation may be performed to detect the presence and the positions of the plurality of substrates W in the cassette 190 from the detection result from the reflective sensor 96 when the hand 10 is moved in the vertical direction. In the configuration described above, the information indicating the thickness is also acquired from the information obtained when performing the scanning operation, which is useful for effectively performing the process when transferring the substrate W.

[19] The substrate transfer system 1 described in any one of [11] to [18], further including: a load presence sensor 94 that detects the substrate W on the hand 10, wherein the transfer control unit 116 controls the substrate transfer robot 2 to transfer the substrate W when the substrate W is detected by the load presence sensor 94, and stops an operation to transfer the substrate W by the substrate transfer robot 2 when no substrate W is detected by the load presence sensor 94.

When the hand 10 is operated to support the substrate W, an error may occur in which the substrate W is not supported by the hand 10 for a certain reason. In the configuration described above, when the error occurs, the transfer operation by the substrate transfer system 1 may be stopped.

[20] The substrate transfer system 1 described in any one of [11] to [19], further including: a load presence sensor 94 that detects the substrate W on the hand 10; and a state determination circuit that determines a holding state of each of the adsorption unit 60, the friction holding unit 70, and the non-contact holding unit 80, based on the detection result from the pressure sensor 92 and a detection result from the load presence sensor 94.

In this case, the state of the action on the substrate W by the three types of holding units of the hand 10 may be identified.

[21] A substrate transfer system 1 including: a substrate transfer robot 2 that includes a hand 10 and transfers a substrate W while supporting the substrate W by the hand 10; a cassette 190 in which the substrate W is placed before or after being transferred by the substrate transfer robot 2; and a transfer control unit that controls the substrate transfer robot 2 to transfer the substrate W between the cassette 190 and a predetermined position distant from the cassette 190, wherein the hand 10 includes an adsorption unit 60 that holds a back surface Wb of the substrate W by adsorption, and is stretchable to lower a height position of an upper end thereof, a friction holding unit 70 that holds the back surface Wb by friction in a state where the adsorption unit 60 supporting the substrate W contracts, and a non-contact holding unit 80 that holds the back surface Wb in a non-contact manner, in a state where the adsorption unit 70 and the friction holding unit 70 hold the back surface Wb.

The substrate transfer system 1 includes the hand 10 provided with the adsorption unit 60, the friction holding unit 70, and the non-contact holding unit 80, which is useful for stabilizing the transfer operation similar to the substrate transfer robot 2 described in [1] above.

[22] A substrate transfer method including: transferring a substrate W by a substrate transfer robot 2 including a hand 10 supporting the substrate W, wherein the hand 10 includes an adsorption unit 60 that holds a back surface Wb of the substrate W by adsorption and is stretchable to lower a height position of an upper end thereof, a friction holding unit 70 that holds the back surface Wb by friction in a state where the adsorption unit 60 supporting the substrate W contracts, and a non-contact holding unit 80 that holds the back surface Wb in a non-contact manner, in a state where the adsorption unit 60 and the friction holding unit 70 hold the back surface Wb, and in the transferring, the substrate transfer robot 2 is controlled to transfer the substrate W in a state where each of the adsorption unit 60, the friction holding unit 70, and the non-contact holding unit holds the back surface Wb.

The substrate transfer method above is useful for stabilizing the transfer operation similar to the substrate transfer robot 2 described in [1] above, since the substrate W is transferred in the state where each of the adsorption unit 60, the friction holding unit 70, and the non-contact holding unit 80 holds the substrate W.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate transfer robot comprising:
a hand configured to support a substrate; and
an arm configured to operate the hand,
wherein the hand includes
an adsorption holder configured to hold a back surface of the substrate by adsorption, and being stretchable to lower a height position of an upper end thereof,
a friction holder configured to hold the back surface of the substrate by friction in a state where the adsorption holder supporting the substrate contracts, and
a non-contact holder configured to hold the back surface of the substrate in a non-contact manner, in a state where the adsorption holder and the friction holder hold the back surface of the substrate.

2. The substrate transfer robot according to claim 1, wherein in a state where the hand is not supporting the substrate, the height position of the upper end of the adsorption holder is higher than a height position of an upper end of the friction holder, and
in a state where the adsorption holder contracts while adsorbing the back surface of the substrate, the back surface of the substrate comes into contact with the upper end of the friction holder.

3. The substrate transfer robot according to claim 2, wherein the adsorption holder is able to contract from a first height position to a second height position, and
the upper end of the friction holder is positioned between the first height position and the second height position.

4. The substrate transfer robot according to claim 1, wherein the non-contact holder is fixed to a predetermined position on the hand,
the adsorption holder contracts such that the back surface of the substrate approaches the non-contact holder, when the substrate is supported by the hand, and
in a state where the adsorption holder contracts to an extent that the back surface of the substrate comes into contact with the upper end of the friction holder, a gap is formed between the upper end of the non-contact holder and the back surface of the substrate.

5. The substrate transfer robot according to claim 1, wherein the hand includes one or more adsorption holders including the adsorption holder, and one or more friction holders including the friction holder,
any one of the one or more adsorption holders or any one of the one or more friction holders holds a first region of the back surface of the substrate,
any one of the one or more adsorption holders or any one of the one or more friction holders holds a second region of the back surface of the substrate arranged together with the first region along a predetermined direction, and
the non-contact holder holds a region between the first region and the second region in the predetermined direction.

6. The substrate transfer robot according to claim 5, wherein the hand further includes a second non-contact holder corresponding to the non-contact holder,
the first region is disposed at a first end of the back surface of the substrate in the predetermined direction,
the second region is disposed at a second end of the back surface of the substrate opposite to the first end, and
any one of the one or more adsorption holders or any one of the one or more friction holders holds a third region disposed between the first region and the second region in the predetermined direction,
the non-contact holder holds a region between the first region and the third region in the predetermined direction, and
the second non-contact holder holds a region between the third region and the second region in the predetermined direction.

7. The substrate transfer robot according to claim 6, wherein a first adsorption holder of the one or more adsorption holders holds the first region disposed at the first end by adsorption, and
a second adsorption holder of the one or more adsorption holders holds the second region disposed at the second end by adsorption.

8. The substrate transfer robot according to claim 1, wherein the friction holder includes a flat holding surface that comes into contact with the back surface of the substrate when the adsorption holder contracts, and
the friction holder is provided such that the holding surface surrounds the adsorption holder.

9. The substrate transfer robot according to claim 1, wherein the hand includes a fork,
the fork is formed to extend in a predetermined direction,
in a width direction orthogonal to the predetermined direction, a width of the fork is narrower than a width of the substrate,
the fork includes the adsorption holder, the friction holder, and the non-contact holder, and
in the width direction, a maximum width of the friction holder is wider than a maximum width of a body of the fork.

10. The substrate transfer robot according to claim 9, wherein the hand further includes a second fork arranged while being spaced apart from the fork in the width direction, and
a portion of the friction holder protrudes from the body of the fork in a space between the body of the fork and the second fork.

11. A substrate transfer system comprising:
the substrate transfer robot according to claim 1;
a pressure sensor configured to detect a pressure of a suction path connected to the adsorption holder;
a transfer controller configured to control the substrate transfer robot to transfer the substrate while supporting the substrate on the hand; and
a transfer condition setting circuit configured to set a transfer condition for transferring the substrate based on a detection result from the pressure sensor.

12. The substrate transfer system according to claim 11, wherein the transfer condition setting circuit sets a transfer speed for transferring the substrate as the transfer condition based on the detection result from the pressure sensor.

13. The substrate transfer system according to claim 12, wherein the transfer condition setting circuit
sets the transfer speed to a reference value when the pressure of the suction path is larger than a predetermined level, and
sets the transfer speed to a value smaller than the reference value when the pressure of the suction path is smaller than the predetermined level.

14. The substrate transfer system according to claim 12, further comprising:
a type identification circuit configured to identify a type of the substrate from a plurality of workpiece types,
wherein the transfer condition setting circuit further refers to an identification result from the type identification circuit in order to set the transfer speed.

15. The substrate transfer system according to claim 14, wherein the plurality of workpiece types include a first type of workpiece and a second type of workpiece having a larger thickness or mass than that of the first type of workpiece,
the transfer condition setting circuit
sets the transfer speed to a reference value, regardless of the identification result from the type identification circuit, when the pressure of the suction path is larger than a predetermined level,
sets the transfer speed to a first value equal to or smaller than the reference value, when the pressure of the suction path is smaller than the predetermined level, and the type of the substrate is identified as the first type of workpiece, and
sets the transfer speed to a second value smaller than the first value, when the pressure of the suction path is smaller than the predetermined level, and the type of the substrate is identified as the second type of workpiece.

16. The substrate transfer system according to claim 12, further comprising:
a thickness information acquisition circuit configured to acquire information indicating a thickness of the substrate,
wherein the transfer condition setting circuit further refers to an acquisition result from the thickness information acquisition circuit in order to set the transfer speed.

17. The substrate transfer system according to claim 16, wherein the transfer condition setting circuit
sets the transfer speed to a reference value, regardless of the acquisition result from the thickness information acquisition circuit, when the pressure of the suction path is larger than a first predetermined level,
sets the transfer speed to a first value equal to or smaller than the reference value, when the pressure of the suction path is smaller than the first predetermined level, and the thickness of the substrate is smaller than a second predetermined level, and
sets the transfer speed to a second value smaller than the first value, when the pressure of the suction path is smaller than the first predetermined level, and the thickness of the substrate is larger than the second predetermined level.

18. The substrate transfer system according to claim 16, further comprising:
a cassette configured to accommodate a plurality of substrates including the substrate, in a state of being arranged in a vertical direction; and
a reflective sensor provided on the hand, and configured to detect each of the plurality of substrates in a state of being accommodated in the cassette,
wherein the thickness information acquisition circuit acquires the information indicating the thickness of the substrate based on a detection result from the reflective sensor when the hand is moved in the vertical direction.

19. The substrate transfer system according to claim 11, further comprising:
a load presence sensor configured to detect the substrate on the hand,
wherein the transfer controller
controls the substrate transfer robot to transfer the substrate when the substrate is detected by the load presence sensor, and
stops an operation to transfer the substrate by the substrate transfer robot when no substrate is detected by the load presence sensor.

20. The substrate transfer system according to claim 11, further comprising:
a load presence sensor configured to detect the substrate on the hand; and
a state determination circuit configured to determine a holding state of each of the adsorption holder, the friction holder, and the non-contact holder, based on the detection result from the pressure sensor and a detection result from the load presence sensor.

21. A substrate transfer system comprising:
a substrate transfer robot including a hand and configured to transfer a substrate while supporting the substrate by the hand;
a cassette in which the substrate is placed before or after being transferred by the substrate transfer robot; and
a transfer controller configured to control the substrate transfer robot to transfer the substrate between the cassette and a predetermined position distant from the cassette,
wherein the hand includes
an adsorption holder configured to hold a back surface of the substrate by adsorption, and being stretchable to lower a height position of an upper end thereof,
a friction holder configured to hold the back surface of the substrate by friction in a state where the adsorption holder supporting the substrate contracts, and
a non-contact holder configured to hold the back surface of the substrate in a non-contact manner, in a state where the adsorption holder and the friction holder hold the back surface of the substrate.

22. A substrate transfer method comprising:
transferring a substrate by a substrate transfer robot including a hand supporting the substrate,
wherein the hand includes
an adsorption holder configured to hold a back surface of the substrate by adsorption, and being stretchable to lower a height position of an upper end thereof,
a friction holder configured to hold the back surface of the substrate by friction in a state where the adsorption holder supporting the substrate contracts, and
a non-contact holder configured to hold the back surface in a non-contact manner, in a state where the adsorption holder and the friction holder hold the back surface of the substrate, and
in the transferring, the substrate transfer robot is controlled to transfer the substrate in a state where each of the adsorption holder, the friction holder, and the non-contact holder holds the back surface of the substrate.
